(19) United States
(12) Patent Application Publication
(10) Pub. No.: US 2024/0170402 A1
(43) Pub. Date: May 23, 2024

(54) SEMICONDUCTOR DEVICE

(71) Applicant: SAMSUNG ELECTRONICS CO., LTD., Suwon-si (KR)

(72) Inventors: Jeonggu SIM, Suwon-si (KR); Jiwook KWON, Suwon-si (KR); Jinwoo JEONG, Suwon-si (KR)

(21) Appl. No.: 18/205,139

(22) Filed: Jun. 2, 2023

(30) Foreign Application Priority Data
Nov. 23, 2022 (KR) 10-2022-0158462

(51) Int. Cl. H01L 23/528

(52) U.S. Cl. CPC H01L 23/5286; H01L 23/5283

(57) ABSTRACT

A semiconductor device includes logic cells including first conductive lines, first power lines, second conductive lines on the first conductive lines, first power lines, and third conductive lines and second power lines on the second conductive lines. The first conductive line, first power line, third conductive line, and second power line extend in a first direction, the second conductive line extends in a second direction crossing the first direction, the second conductive line includes separation areas near a boundary of the logic cell, the separation areas are alternately positioned at a lower side and an upper side based on the boundary of the logic cell in zigzag form. The first conductive lines and the second conductive lines overlap first hit points to which the first conductive lines and the second conductive lines can be connected, except for a point adjacent to the separation area of the second conductive line.

### CROSS-REFERENCE TO RELATED APPLICATION

This application claims priority to and the benefit of Korean Patent Application No. 10-2022-0158462 filed in the Korean Intellectual Property Office on Nov. 23, 2022, the entire contents of which are incorporated herein by reference.

### BACKGROUND

### 1. Field

The present disclosure relates to a semiconductor device.

### 2. Description of the Related Art

A semiconductor is a material belonging to an intermediate condition between a conductor and an insulator. A semiconductor can conduct electricity under predetermined conditions. Various semiconductor devices can be manufactured by using a semiconductor material. For example, a memory device and the like may be manufactured. Semiconductor devices may be used in various electronic devices.

According to a trend in down-sizing and high integration of electronic devices, it is desirable to form fine patterns in configuring semiconductor devices. However, with the forming of fine patterns, there is a risk that a defect such as a short circuit between electrodes or wires made of such fine patterns could occur.

### SUMMARY

Embodiments are directed to a semiconductor device, comprising a plurality of logic cells, wherein each of the plurality of logic cells includes a plurality of first conductive lines and a plurality of first power lines, a plurality of second conductive lines disposed on the plurality of first conductive lines and the plurality of first power lines, and a plurality of third conductive lines and a plurality of second power lines disposed on the plurality of second conductive lines, the first conductive line, the first power line, the third conductive line, and the second power line extend in a first direction, the second conductive line extends in a second direction crossing the first direction, the second conductive line includes separation areas disposed adjacent to a boundary of the logic cell, the separation areas of the second conductive line are alternately positioned at a lower side and an upper side based on the boundary of the logic cell to be disposed in a zigzag form, and points at which the first conductive lines and the second conductive lines overlap have first hit points to which the first conductive lines and the second conductive lines are able to be connected, except for a point adjacent to the separation area of the second conductive line.

Embodiments may be directed to a semiconductor device comprising a plurality of logic cells, wherein each of the plurality of logic cell includes a plurality of first conductive lines and a plurality of first power lines, a plurality of second conductive lines disposed on the plurality of first conductive lines and the plurality of first power lines, and a plurality of third conductive lines and a plurality of second power lines disposed on the plurality of second conductive lines, the first conductive line, the first power line, the third conductive line, and the second power line extending in a first direction, the second conductive line extending in a second direction crossing the first direction, the second conductive line includes a separation area disposed adjacent to a boundary of the logic cell, the separation areas of the second conductive line are alternately positioned at a lower side and an upper side based on the boundary of the logic cell to be disposed in a zigzag form, and points at which the second conductive lines and the third conductive lines overlap have second hit points to which the second conductive lines and the third conductive lines are able to be connected, except for a point adjacent to the separation area of the second conductive line.

Embodiments may provide a semiconductor device comprising a plurality of logic cells, wherein each of the plurality of logic cell includes a first power line positioned at two edges of the logic cell facing each other, a first conductive line positioned between the first power lines, and a second conductive line crossing the first power line and the first conductive line, a second power line that crosses the second conductive line and is positioned at the two edges of the logic cell facing each other, and a third conductive line positioned between the second power lines, wherein the second conductive line includes a separation area disposed adjacent to a boundary of the logic cell, the separation areas of the second conductive line are alternately positioned at a lower side and an upper side based on the boundary of the logic cell to be disposed in a zigzag form, points at which the first conductive lines and the second conductive lines overlap have first hit points to which the first conductive lines and the second conductive lines are able to be connected, except for a point adjacent to the separation area of the second conductive line, and points at which the second conductive lines and the third conductive lines overlap have second hit points to which the second conductive lines and the third conductive lines are able to be connected, except for a point adjacent to the separation area of the second conductive line.

### BRIEF DESCRIPTION OF THE DRAWINGS

Features will become apparent to those of skill in the art by describing in detail exemplary embodiments with reference to the attached drawings in which:

FIG. 1A, FIG. 1B, and FIG. 2 illustrate top plan views of some layers of a semiconductor device according to an embodiment.

FIG. 3 illustrates a cross-sectional view taken along line A-A′ of FIG. 2.

FIG. 4A and FIG. 4B illustrate top plan views of some layers of a semiconductor device according to a reference example.

FIG. 5 illustrates a top plan view of some layers of a semiconductor device according to a reference example.

FIG. 6 illustrates a top plan view of some layers of a semiconductor device according to an embodiment.

FIG. 7 illustrates a top plan view of some layers of a semiconductor device according to a reference example.

FIG. 8 illustrates a top plan view of some layers of a semiconductor device according to an embodiment.

FIG. 9A and FIG. 9B illustrate top plan views of some layers of a semiconductor device according to an embodiment.

FIG. 10A and FIG. 10B illustrate top plan views of some layers of a semiconductor device according to an embodiment.

FIG. 11A and FIG. 11B illustrate top plan views of some layers of a semiconductor device according to an embodiment.

FIG. 12A and FIG. 12B illustrate top plan views of some layers of a semiconductor device according to an embodiment.

FIG. 13A and FIG. 13B illustrate top plan views of some layers of a semiconductor device according to an embodiment.

FIG. 14A and FIG. 14B illustrate top plan views of some layers of a semiconductor device according to an embodiment.

FIG. 15A and FIG. 15B illustrate top plan views of some layers of a semiconductor device according to an embodiment.

FIG. 16A and FIG. 16B illustrate top plan views of some layers of a semiconductor device according to an embodiment.

FIG. 17A and FIG. 17B illustrate top plan views of some layers of a semiconductor device according to an embodiment.

FIG. 18A and FIG. 18B illustrate top plan views of some layers of a semiconductor device according to an embodiment.

FIG. 19A and FIG. 19B illustrate top plan views of some layers of a semiconductor device according to an embodiment.

FIG. 20 illustrates two types of cells configuring a semiconductor device according to an embodiment.

FIG. 21 and FIG. 22 illustrate disposition forms of a plurality of cells configuring a semiconductor device according to an embodiment.

### DETAILED DESCRIPTION

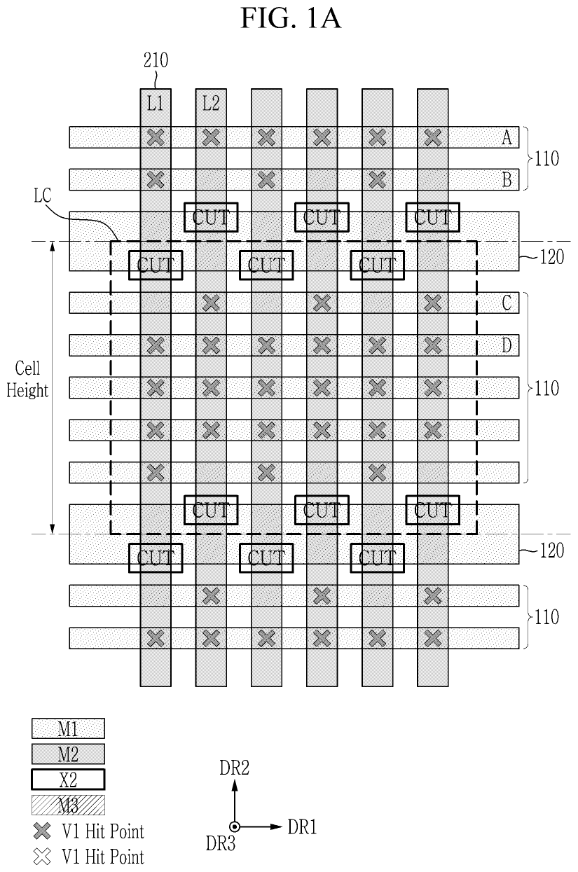

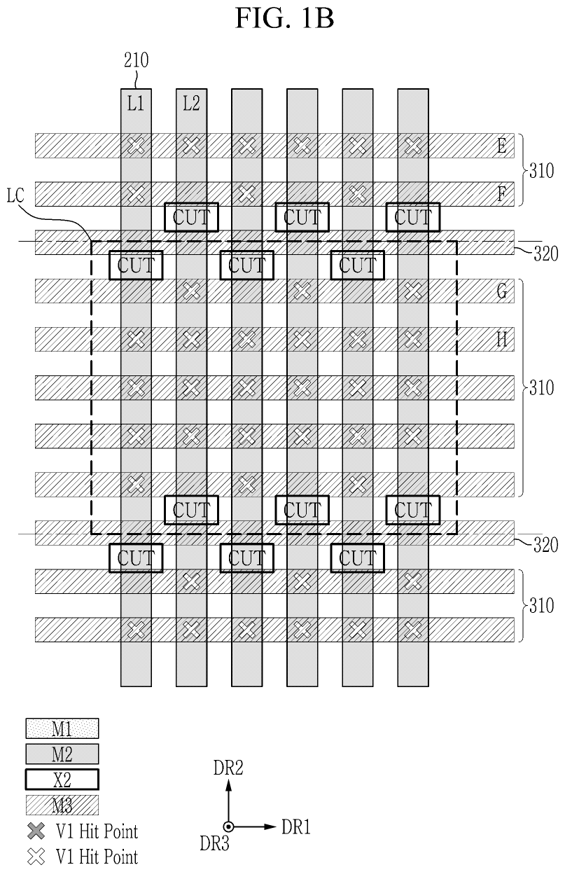

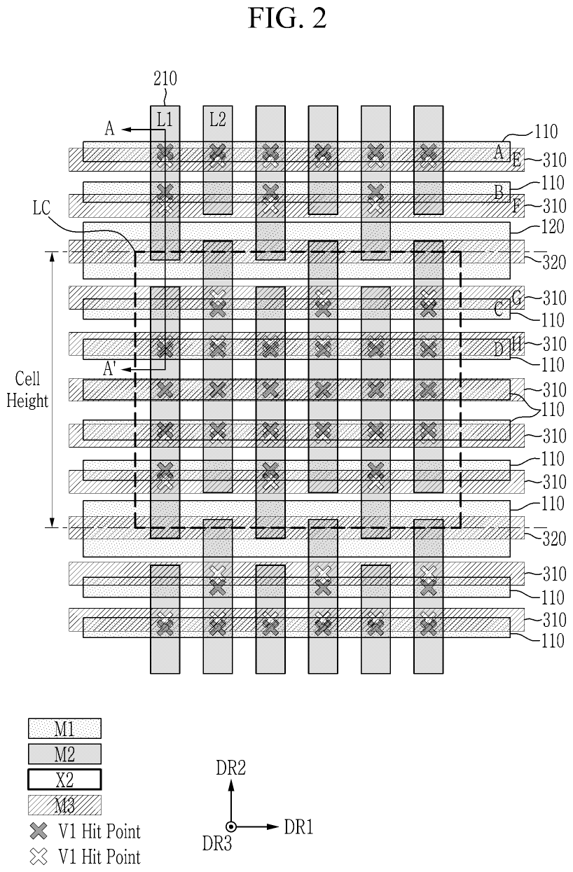

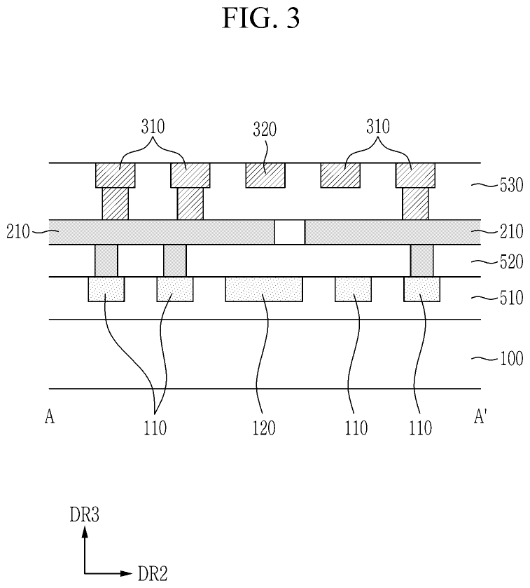

Hereinafter, a semiconductor device according to an embodiment will be described with reference to FIG. 1A, FIG. 1B, FIG. 2, and FIG. 3.

FIG. 1A, FIG. 1B, and FIG. 2 illustrate top plan views of some layers of a semiconductor device according to an embodiment (according to the legend provided in the lower left of FIGS. 1A, 1B, and 2). FIG. 3 illustrates a cross-sectional view taken along line A-A′in FIG. 2. FIG. 1A and FIG. 1B respectively illustrate some of layers illustrated in FIG. 2. FIG. 1A illustrates a first conductive layer M1 and a second conductive layer M2, and FIG. 1B illustrates the second conductive layer M2 and a third conductive layer M3.

Referring to FIG. 3, a semiconductor device according to an embodiment may include a substrate 100; a plurality of first conductive lines 110 and a plurality of first power lines 120 positioned on the substrate 100. The semiconductor device may also include a plurality of second conductive lines 210 positioned on the plurality of first conductive lines 110 and the plurality of first power lines 120, a plurality of third conductive lines 310 and a plurality of second power lines 320 positioned on the plurality of second conductive lines 210.

The semiconductor device according to embodiments may include a plurality of logic cells LC. Each of the plurality of logic cells LC may include circuit patterns for configuring various circuits. The first conductive line 110, the first power line 120, the second conductive line 210, the third conductive line 310, and the second power line 320 may be circuit patterns that constitute the logic cell LC. The plurality of logic cells LC may be arranged in a matrix format along a first direction DR1 and a second direction DR2. The plurality of logic cells LC may include the same or similar circuit patterns, or may include different circuit patterns. The plurality of logic cells LC may have a function of performing various logic functions. At least some of the plurality of logic cells LC may perform the same logic function. At least some of the plurality of logic cells LC may perform different logic functions. The plurality of logic cells LC may include various types of logic cells including a plurality of circuit elements. For example, the plurality of logic cells LC may include an AND, a NAND, an OR, a NOR, an exclusive OR (XOR), an exclusive NOR (XNOR), an inverter (INV), an adder (ADD), a buffer (BUF), a delay (DLY), a filter (FIL), a multiplexer (MXT/MXIT), an OAI (OR/AND/INVERTER), an AO (AND/OR), an AOI (AND/OR/INVERTER), a D-flipflop, a reset flipflop, a master-slave flip-flop, a latch, or a combination thereof, as non-limiting examples.

The plurality of first conductive lines 110 may extend in parallel along the first direction DR1. The plurality of first conductive lines 110 may be positioned to be spaced apart from each other in the second direction DR2 crossing the first direction DR1. The second direction DR2 may be a direction perpendicular to the first direction DR1.

The plurality of first power lines 120 may extend in a direction parallel to the first conductive line 110. The plurality of first power lines 120 may extend in parallel along the first direction DR1. The plurality of first power lines 120 may be positioned to be spaced apart from each other along the second direction DR2. The first power line 120 may be positioned to be spaced apart from the first conductive line 110 along the second direction DR2. A width of the first power line 120 may be wider than that of the first conductive line 110. For example, the width of the first power line 120 may be about twice or more than the width of the first conductive line 110. In some implementations, and the widths of the first power line 120 and the first conductive line 110 may be vary. The first conductive line 110 and the first power line 120 may have a predetermined thickness along a third direction DR3 perpendicular to the first direction DR1 and the second direction DR2.

In a plan view, the logic cell LC may have a substantially quadrangular shape. In some implementations, the planar shape of the logic cell LC may vary. Two edges of the logic cell LC facing each other may overlap different first power lines 120, respectively. For example, the first power line 120 may be positioned at a boundary between two adjacent logic cells LC. In this case, two edges of the logic cell LC overlapping the first power line 120 may be parallel to the first direction DR1. For example, an upper edge of the logic cell LC may overlap the first power line 120 transmitting a power voltage VDD, and a lower edge of the logic cell LC may overlap the first power line 120 transmitting a ground voltage VSS. The logic cell LC may have a predetermined cell height. For example, the cell height of the logic cell LC may be about 140 nm.

The plurality of first conductive lines 110 may be positioned between two adjacent first power lines 120. For example, five first conductive lines 110 may be positioned between two first power lines 120. In this case, five first conductive lines 110 may be positioned within one logic cell LC. However, in some implementations, the number of the first power lines 120 and the number of the first conductive lines 110 positioned within one logic cell LC may vary.

The first conductive line 110 and the first power line 120 may be positioned on the same layer. The layer on which the first conductive line 110 and the first power line 120 are positioned is referred to as the first conductive layer M1. A first insulating layer 510 may be positioned between the substrate 100 and the first conductive layer M1. The first conductive layer M1 may include a metallic material such as Ti, Ta, or W and may be formed as a single layer or as a multilayer. The first insulating layer 510 may include an insulating material.

In FIG. 3, the first insulating layer 510 is shown to be directly positioned on the substrate 100, but in some implementations, several elements may be positioned between the substrate 100 and the first insulating layer 510. For example, an active area defined by an isolating film may be positioned on the substrate 100, and a transistor including a channel pattern, a gate electrode, a source/drain pattern, and the like may be positioned on the active area. In this case, the transistor may be formed as a field effect transistor (for example, FINFET, MBCFET, GAA, or the like) having a gate electrode three-dimensionally surrounding a channel. The first conductive line 110 and the first power line 120 may be wires that transmit a predetermined signal or a predetermined constant voltage to such a transistor.

The plurality of second conductive lines 210 may extend in a direction crossing the plurality of first conductive lines 110 and the plurality of first power lines 120. The plurality of second conductive lines 210 may extend in parallel along the second direction DR2. The plurality of second conductive lines 210 may be positioned to be spaced apart from each other along the first direction DR1.

The second conductive line 210 is shown as one wire extending from one end portion to the other end portion along the second direction DR2, as a non-limiting example. In some implementations, the second conductive line 210 may be formed of a plurality of wires that are cut at predetermined positions. A point at which the second conductive line 210 can be separated is indicated as a separation area CUT. In an area marked as the separation area CUT, the second conductive line 210 may be separated or may be connected without being separated. FIG. 1A and FIG. 1B show the separation area CUT that may be separated in a state in which the second conductive line 210 is connected, while FIGS. 2 and 3 show a state in which the second conductive line 210 is separated in all of the separation areas CUT.

The second conductive line 210 positioned in one column may include a plurality of separation areas CUT. For example, the second conductive line 210 may be separated around the boundary of the logic cell LC. That is, the separation area CUT of the second conductive line 210 may be positioned to be adjacent to the boundary of the logic cell LC. The separation area CUT of the second conductive line 210 may overlap at least a portion of the first power line 120. The separation area CUT of the second conductive line 210 may not overlap the boundary of the logic cell LC. The separation areas CUT of the second conductive line 210 may be alternately positioned at a lower side and an upper side based on the boundary of the logic cell LC, and may be disposed in a zigzag form. The separation area CUT of the second conductive line 210 may alternately overlap a lower edge and an upper edge of the first power line 120.

The disposition form of the separation areas CUT of the second conductive line 210 adjacent to the upper edge of the logic cell LC may be substantially the same as the disposition form of the separation area CUT of the second conductive line 210 adjacent to the lower edge of the logic cell LC. For example, the separation areas CUT of the second conductive line 210 positioned at a first column L1 may all be positioned at the lower side of the boundary of the logic cell LC. For example, the separation areas CUT of the second conductive line 210 positioned at a second column L2 may all be positioned at the upper side of the boundary of the logic cell LC.

The layer on which the second conductive line 210 is positioned is referred to as the second conductive layer M2. In the present embodiment, first, the second conductive line 210 positioned in the second conductive layer M2 is formed as a single wire connected along the second direction DR2. Then, by removing at least a portion of the second conductive line 210 through an additional process, the separation area CUT may be formed. For example, the separation area CUT may be formed by using a separate mask X2.

A second insulating layer 520 may be positioned between the first conductive layer M1 and the second conductive layer M2. The second conductive layer M2 may include a metallic material. The second conductive layer M2 may be formed as a single layer or a multilayer. The second insulating layer 520 may include an insulating material.

A wire positioned on the second conductive layer M2 may be connected to a wire positioned on the first conductive layer M1 through a via-hole formed in the second insulating layer 520. For example, the second conductive line 210 may be connected to the first conductive line 110 through the via-hole formed in the second insulating layer 520. A position at which the via-hole may be formed in the second insulating layer 520 is indicated as a first hit point (V1 Hit Point). The via-hole may or may not actually be formed in the second insulating layer 520 at the point indicated as the first hit point (V1 Hit Point). That is, the second conductive line 210 may be connected to the first conductive line 110 at least one of points marked with the first hit point (V1 Hit Point).

The first hit point (V1 Hit Point) may be positioned at a point at which the first conductive line 110 and the second conductive line 210 overlap. The first hit point (V1 Hit Point) is not positioned at all points at which the first conductive line 110 and the second conductive line 210 overlap. Among the points at which the first conductive lines 110 and the second conductive lines 210 overlap, the first hit point (V1 Hit Point) is not positioned at a point adjacent to the separation area CUT.

For example, the first hit point (V1 Hit Point) may be positioned at a point at which the first conductive line 110 positioned at a first row A and the second conductive line 210 positioned at the first column L1 overlap. The first hit point (V1 Hit Point) may be positioned at a point at which the first conductive line 110 positioned at a second row B and the second conductive line 210 positioned at the first column L1 overlap. The first hit point (V1 Hit Point) may be positioned at a point at which the first conductive line 110 positioned at a fourth row D and the second conductive line 210 positioned at the first column L1 overlap. The separation area CUT of the second conductive line 210 positioned at the first column L1 may be adjacent to the first conductive line 110 positioned at a third row C. The first hit point (V1 Hit Point) may not be positioned at a point at which the first conductive line 110 positioned at the third row C and the second conductive line 210 positioned at the first column L1 overlap.

The first hit point (V1 Hit Point) may be positioned at a point at which the first conductive line 110 positioned at the first row A and the second conductive line 210 positioned at the second column L2 overlap. The first hit point (V1 Hit Point) may be positioned at a point at which the first conductive line 110 positioned at the third row C and the second conductive line 210 positioned at the second column L2 overlap. The first hit point (V1 Hit Point) may be positioned at a point at which the first conductive line 110 positioned at the fourth row D and the second conductive line 210 positioned at the second column L2 overlap. The separation area CUT of the second conductive line 210 positioned at the second column L2 may be adjacent to the first conductive line 110 positioned at the second row B. The first hit point (V1 Hit Point) may not be positioned at the point at which the first conductive line 110 positioned at the second row B and the second conductive line 210 positioned at the second column L2 overlap.

In the present embodiment, one second conductive line 210 may overlap five first conductive lines 110 within one logic cell LC. In this case, four of the five points at which the one second conductive line 210 and the five first conductive lines 110 overlap may have the first hit point (V1 Hit Point). In the present embodiment, by disposing the separation areas CUT in a zigzag form, while sufficiently securing a process margin between the separation area CUT and the first hit point (V1 Hit Point), the number of the first hit points (V1 Hit Point) may be sufficiently provided.

The plurality of third conductive lines 310 may extend in a direction crossing the plurality of second conductive lines 210. The plurality of third conductive lines 310 may extend in a direction parallel to the plurality of first conductive lines 110 and the plurality of first power lines 120. The third conductive line 310 may overlap the first conductive line 110. The plurality of third conductive lines 310 may extend in parallel along the first direction DR1. The plurality of third conductive lines 310 may be positioned to be spaced apart from each other along the second direction DR2.

The plurality of second power lines 320 may extend in a direction crossing the plurality of second conductive lines 210. The plurality of second power lines 320 may extend in a direction parallel to the third conductive line 310. The plurality of second power lines 320 may extend in a direction parallel to the plurality of first conductive lines 110 and the plurality of first power lines 120. The second power line 320 may overlap the first power line 120. The plurality of second power lines 320 may extend in parallel along the first direction DR1. The plurality of second power lines 320 may be positioned to be spaced apart from each other along the second direction DR2. The second power line 320 may be positioned to be spaced apart from the second conductive line 310 along the second direction DR2. A width of the second power line 320 may be similar to that of the third conductive line 310, as a non-limiting example. The widths of the second power line 320 and the third conductive line 310 may vary.

Two edges of the logic cell LC facing each other may overlap different second power lines 320, respectively. For example, the second power line 320 may be positioned at a boundary between two adjacent logic cells LC. In this case, two edges of the logic cell LC overlapping the second power line 320 may be parallel to the first direction DR1. For example, an upper edge of the logic cell LC may overlap one second power line 320, and a lower edge of the logic cell LC may overlap another second power line 320.

The separation area CUT of the second conductive line 210 may overlap at least a portion of the second power line 320, as a non-limiting example. The separation area CUT of the second conductive line 210 may not overlap the second power line 320. The separation areas CUT of the second conductive line 210 may be alternately positioned at lower and upper sides of the second power line 320, and may be disposed in a zigzag form.

The plurality of third conductive lines 310 may be positioned between two adjacent second power lines 320. For example, five third conductive lines 310 may be positioned between two second power lines 320. In this case, five third conductive lines 310 may be positioned within one logic cell LC. However, the number of the second power lines 320 and the number of the third conductive lines 310 positioned within one logic cell LC are not limited thereto, and may vary.

The third conductive line 310 and the second power line 320 may be positioned on the same layer. The layer on which the third conductive line 310 and the second power line 320 are positioned is referred to as the third conductive layer M3. A third insulating layer 530 may be positioned between the second conductive layer M2 and the third conductive layer M3. The third conductive layer M3 may include a metallic material. The third conductive layer M3 may be formed as a single layer or a multilayer. The third insulating layer 530 may include an insulating material.

A wire positioned on the third conductive layer M3 may be connected to a wire positioned on the second conductive layer M2 through a via-hole formed in the third insulating layer 530. For example, the third conductive line 310 may be connected to the second conductive line 210 through the via-hole formed in the third insulating layer 530. A position at which the via-hole may be formed in the third insulating layer 530 is indicated as a second hit point (V2 Hit Point). The via-hole may or may not actually be formed in the third insulating layer 530 at the point indicated as the second hit point (V2 Hit Point). That is, the third conductive line 310 may be connected to the second conductive line 210 at least one of points marked as a second hit point (V2 Hit Point).

The second hit point (V2 Hit Point) may be positioned at a point at which the second conductive line 210 and the third conductive line 310 overlap. The second hit point (V2 Hit Point) is not positioned at all points at which the second conductive line 210 and the third conductive line 310 overlap. Among the points at which the second conductive lines 210 and the third conductive lines 310 overlap, the second hit point (V2 Hit Point) is not positioned at a point adjacent to the separation area CUT.

For example, the second hit point (V2 Hit Point) may be positioned at a point at which the third conductive line 310 positioned at a first row E and the second conductive line 210 positioned at the first column L1 overlap. The second hit point (V2 Hit Point) may be positioned at a point at which the third conductive line 310 positioned at a second row F and the second conductive line 210 positioned at the first column L1 overlap. The second hit point (V2 Hit Point) may be positioned at a point at which the third conductive line 310 positioned at a fourth row H and the second conductive line 210 positioned at the first column L1 overlap. The separation area CUT of the second conductive line 210 positioned at the first column L1 may be adjacent to the third conductive line 310 positioned at a third row G. The second hit point (V2 Hit Point) may not be positioned at a point at which the third conductive line 310 positioned at the third row G and the second conductive line 210 positioned at the first column L1 overlap.

The second hit point (V2 Hit Point) may be positioned at a point at which the third conductive line 310 positioned at the first row E and the second conductive line 210 positioned at the second column L2 overlap. The second hit point (V2 Hit Point) may be positioned at a point at which the third conductive line 310 positioned at the third row G and the second conductive line 210 positioned at the second column L2 overlap. The second hit point (V2 Hit Point) may be positioned at a point at which the third conductive line 310 positioned at the fourth row H and the second conductive line 210 positioned at the second column L2 overlap. The separation area CUT of the second conductive line 210 positioned at the second column L2 may be adjacent to the third conductive line 310 positioned at the second row F. The second hit point (V2 Hit Point) may not be positioned at a point at which the third conductive line 310 positioned at the second row F and the second conductive line 210 positioned at the second column L2 overlap.

In the present embodiment, one second conductive line 210 may overlap five third conductive lines 310 within one logic cell LC. In this case, four of the five points at which the one second conductive line 210 and the five third conductive lines 310 overlap may have the second hit point (V2 Hit Point). In the present embodiment, the separation areas CUT are disposed in a zigzag form, and the second hit point (V2 Hit Point) is not formed at a point adjacent to the separation area CUT, so that a sufficient number of the second hit points (V2 Hit Point) may be provided while sufficiently securing a process margin between the separation area CUT and the second hit point (V2 Hit Point).

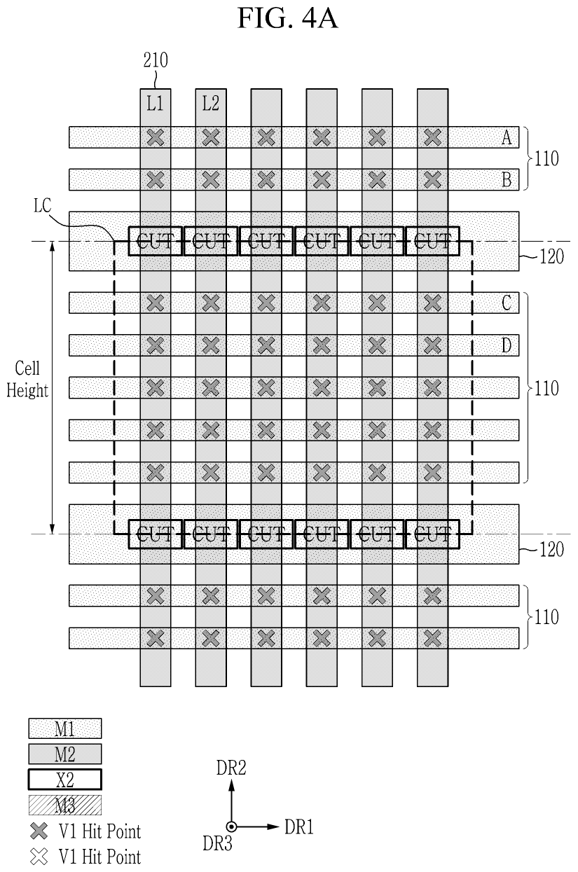

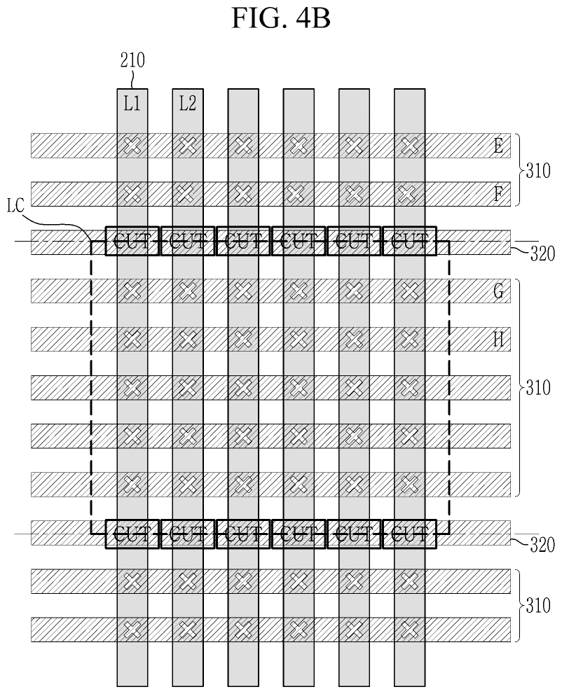

Hereinafter, for comparison with the semiconductor device according to the embodiment, a semiconductor device according to a reference example will be described with reference to FIG. 4A and FIG. 4B.

FIG. 4A and FIG. 4B illustrate top plan views of some layers of a semiconductor device according to a reference example. FIG. 4A illustrates the first conductive layer M1 and the second conductive layer M2, and FIG. 4B illustrates the second conductive layer M2 and the third conductive layer M3.

Since many parts of the semiconductor device according to the reference example are the same as the semiconductor device according to the embodiment, a description thereof will not be repeated and differences will be mainly described. In addition, the same reference numerals are used for components that are the same as those of the embodiment.

As shown in FIG. 4A and FIG. 4B, the semiconductor device according to the reference embodiment includes: a plurality of first conductive lines 110 and a plurality of first power lines 120 positioned on the substrate 100; a plurality of second conductive lines 210 positioned on the plurality of first conductive lines 110 and the plurality of first power lines 120; and a plurality of third conductive lines 310 and a plurality of second power lines 320 positioned on the plurality of second conductive lines 210.

The plurality of first conductive lines 110 and the plurality of first power lines 120 may extend in parallel along the first direction DR1. The plurality of second conductive lines 210 may extend in parallel along the second direction DR2.

The second conductive line 210 may include the separation area CUT. The separation area CUT of the second conductive line 210 may overlap the first power line 120. The separation area CUT of the second conductive line 210 may overlap a boundary of the logic cell LC. The separation area CUT of the second conductive line 210 may be disposed in a line along the boundary of the logic cell LC. That is, the separation area CUT of the second conductive line 210 may be disposed in a line along the first direction DR1.

The second conductive line 210 may be connected to the first conductive line 110 at least one of points marked with the first hit point (V1 Hit Point). The first hit point (V1 Hit Point) may be positioned at all points at which the first conductive line 110 and the second conductive line 210 overlap. Among the points at which the first conductive lines 110 and the second conductive lines 210 overlap, the first hit point (V1 Hit Point) may also be positioned at a point adjacent to the separation area CUT.

For example, the first hit point (V1 Hit Point) may be positioned at all of the points at which the first conductive lines 110 positioned at the first row A, the second row B, the third row C, the fourth row D, and the second conductive line 210 positioned at the first column L1 overlap. The first hit point (V1 Hit Point) may also be positioned at all of the points at which the first conductive lines 110 positioned at the first row A, the second row B, the third row C, the fourth row D, and the second conductive line 210 positioned at the second column L2 overlap.

In the reference example, one second conductive line 210 may overlap five first conductive lines 110 within one logic cell LC. In this case, all of the five points at which the one second conductive line 210 and the five first conductive lines 110 overlap may have the first hit point (V1 Hit Point). In the reference example, since the separation areas CUT are arranged in a line, it may be difficult to sufficiently secure a process margin between the separation area CUT and the first hit point (V1 Hit Point). In order to secure the process margin, when the first hit point (V1 Hit Point) is not formed at the point at which the first conductive line 110 positioned at the second row B and the third row C adjacent to the separation area CUT and the second conductive line 210 overlap each other, the number of the first hit points (V1 Hit Point) may be insufficient.

The plurality of third conductive lines 310 and the plurality of second power lines 320 may extend in parallel along the first direction DR1. The separation area CUT of the second conductive line 210 may overlap the second power line 320. The separation area CUT of the second conductive line 210 may be disposed in a line along the second power line 320.

The third conductive line 310 may be connected to the second conductive line 210 at least one of points marked with the second hit point (V1 Hit Point). The second hit point (V2 Hit Point) may be positioned at all points at which the second conductive lines 210 and the third conductive lines 310 overlap. Among the points at which the second conductive lines 210 and the third conductive lines 310 overlap, the second hit point (V2 Hit Point) may also be positioned at a point adjacent to the separation area CUT.

For example, the second hit point (V2 Hit Point) may be positioned at all of the points at which the first conductive lines 310 positioned at the first row E, the second row F, the third row G, the fourth row H and second conductive line 210 positioned at the first column L1 overlap. The second hit point (V2 Hit Point) may also be positioned at all of the points at which the third conductive lines 310 positioned at the first row E, the second row F, the third row G, the fourth row H, and the second conductive line 210 positioned at the second column L2 overlap.

In the reference example, one second conductive line 210 may overlap five third conductive lines 310 within one logic cell LC. In this case, all of the five points at which the one second conductive line 210 and the five third conductive lines 310 overlap may have the second hit point (V2 Hit Point). In the reference example, since the separation areas CUT are arranged in a line, it may be difficult to sufficiently secure a process margin between the separation area CUT and the second hit point (V2 Hit Point). In order to secure the process margin, when the second hit point (V2 Hit Point) is not formed at the point at which the third conductive line 310 positioned at the second row B and the third row C adjacent to the separation area CUT and the second conductive line 210 overlap each other, the number of the second hit points (V2 Hit Point) may be insufficient.

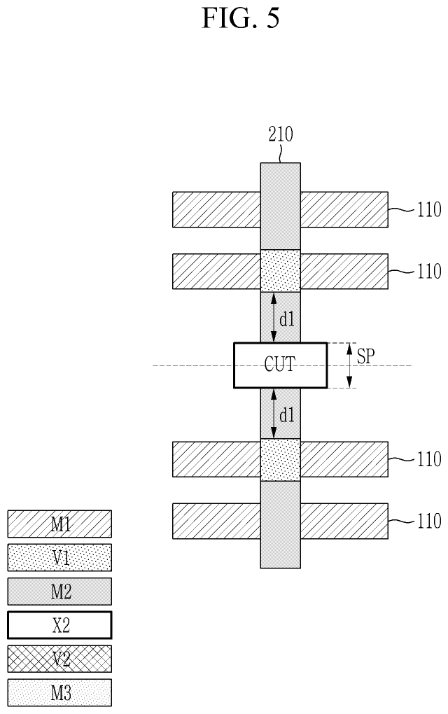

Hereinafter, a semiconductor device according to an embodiment and a semiconductor device according to a reference example will be compared and described with reference to FIG. 5 to FIG. 8.

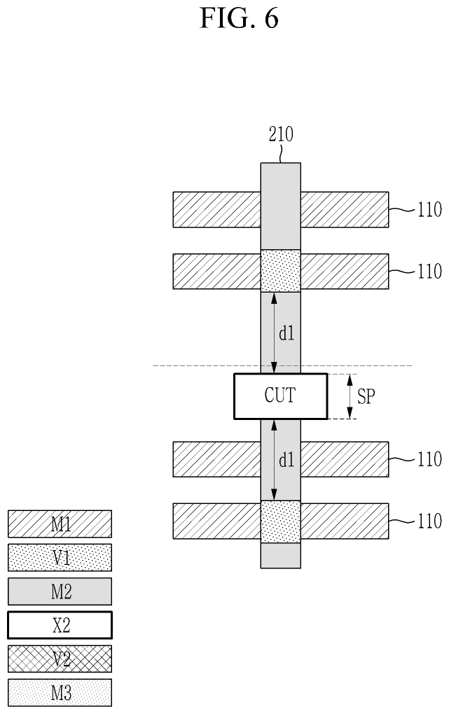

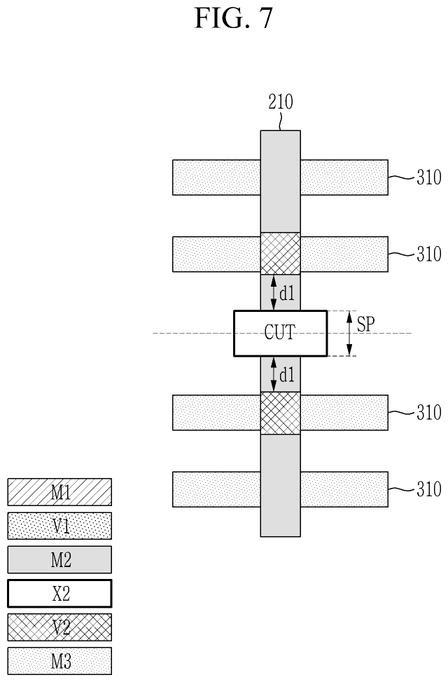

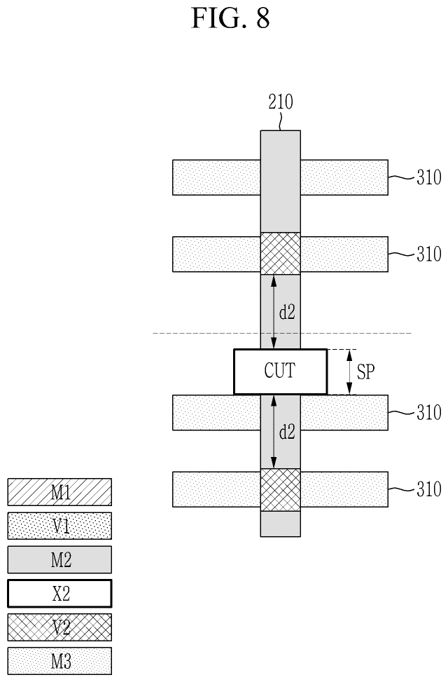

FIG. 5 illustrates a top plan view of some layers of a semiconductor device according to a reference example, and FIG. 6 illustrates a top plan view of some layers of a semiconductor device according to an embodiment. FIG. 7 illustrates a top plan view of some layers of a semiconductor device according to a reference example, and FIG. 8 illustrates a top plan view of some layers of a semiconductor device according to an embodiment. FIG. 5 and FIG. 6 respectively illustrate the first conductive layer M1 and the second conductive layer M2, and FIG. 7 and FIG. 8 respectively illustrate the second conductive layer M2 and the third conductive layer M3.

As shown in FIG. 5, in the semiconductor device according to the reference example, the separation area CUT of the second conductive line 210 may be positioned at a cell boundary of the logic cell. Accordingly, the second conductive line 210 is separated at the cell boundary of the logic cell. In this case, a distance Sp between the second conductive lines 210 separated by the separation area CUT may be about 14 nm.

In the semiconductor device according to the reference example, a first via-hole V1 may be formed at a portion at which the first conductive line 110 adjacent to the separation area CUT of the second conductive line 210 and the second conductive line 210 overlap. The second conductive line 210 may be connected to the first conductive line 110 through the first via-hole V1. In this case, a distance d1 between the separation area CUT and the first via-hole V1, that is, a distance from an end portion of the second conductive line 210 to the first via-hole V1, may be about 15 nm.

As shown in FIG. 6, in the semiconductor device according to the embodiment, the separation area CUT of the second conductive line 210 may be positioned at a point away from the cell boundary of the logic cell. For example, the separation area CUT of the second conductive line 210 may be disposed under the cell boundary of the logic cell. In this case, the distance Sp between the second conductive lines 210 separated by the separation area CUT may be about 14 nm.

In the semiconductor device according to the embodiment, the first via-hole V1 is not formed at a portion at which the first conductive line 110 adjacent to the separation area CUT of the second conductive line 210 and the second conductive line 210 overlap. The first via-hole V1 may be formed at a portion at which the first conductive line 110 away from the separation area CUT of the second conductive line 210 and the second conductive line 210 overlap each other. The second conductive line 210 may be connected to the first conductive line 110 through the first via-hole V1. In this case, the distance d1 between the separation area CUT and the first via-hole V1, that is, a distance from an end portion of the second conductive line 210 to the first via-hole V1, may be about 25.5 nm. Therefore, the semiconductor device according to the embodiment may secure a wider process margin between the separation area CUT and the first via-hole V1 than the reference example.

As shown in FIG. 7, in the semiconductor device according to the reference example, a second via-hole V2 may be formed at a portion at which the third conductive line 310 adjacent to the separation area CUT of the second conductive line 210 and the second conductive line 210 overlap. The third conductive line 310 may be connected to the second conductive line 210 through the second via-hole V2. In this case, a distance d2 between the separation area CUT and the second via-hole V2, that is, a distance from an end portion of the second conductive line 210 to the second via-hole V2, may be about 9 nm.

As shown in FIG. 8, in the semiconductor device according to the embodiment, the second via-hole V1 is not formed at a portion at which the third conductive line 310 adjacent to the separation area CUT of the second conductive line 210 and the second conductive line 210 overlap. The second via-hole V2 may be formed at a portion at which the third conductive line 310 away from the separation area CUT of the second conductive line 210 and the second conductive line 210 overlap each other. The third conductive line 310 may be connected to the second conductive line 210 through the second via-hole V2. In this case, the distance d2 between the separation area CUT and the second via-hole V2, that is, a distance from an end portion of the second conductive line 210 to the second via-hole V2, may be about 21 nm. Therefore, the semiconductor device according to the embodiment may secure a wider process margin between the separation area CUT and the second via-hole V2 than the reference example.

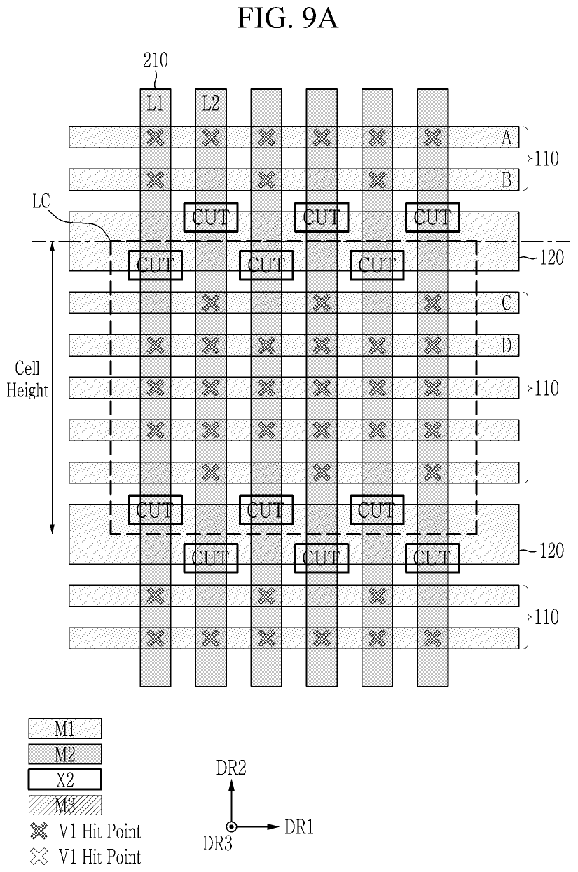

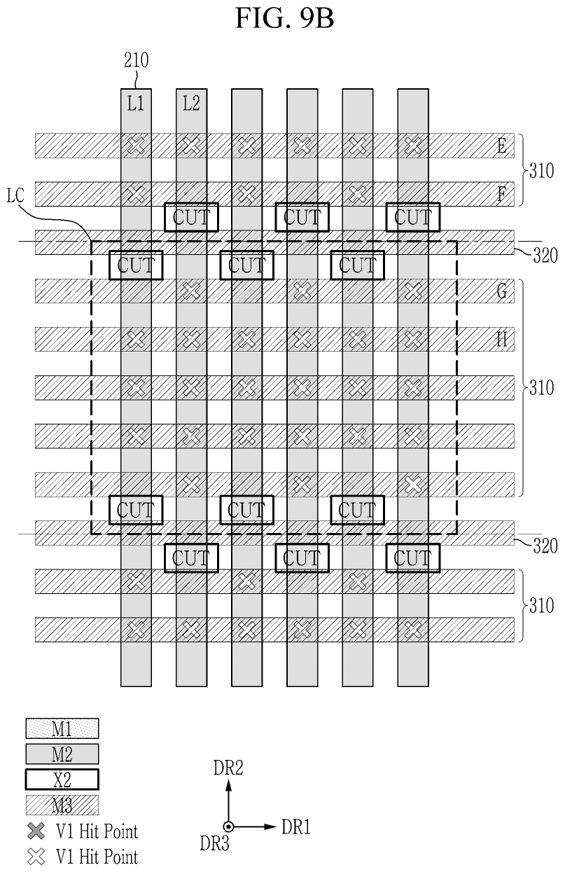

Hereinafter, a semiconductor device according to an embodiment will be described with reference to FIG. 9A and FIG. 9B.

FIG. 9A and FIG. 9B illustrate top plan views of some layers of a semiconductor device according to an embodiment. FIG. 9A illustrates the first conductive layer M1 and the second conductive layer M2, and FIG. 9B illustrates the second conductive layer M2 and the third conductive layer M3.

Since many parts of the embodiment shown in FIG. 9A and FIG. 9B are the same as the embodiment shown in FIG. 1A to FIG. 3, a description thereof will not be repeated and differences will be mainly described. In addition, the same reference numerals are used for components that are the same as those of the previous embodiment. In the present embodiment, the disposition form of the separation area of the second conductive line is partially different from that of the previous embodiment.

As shown in FIG. 9A and FIG. 9B, a semiconductor device according to an embodiment includes: a plurality of first conductive lines 110 and a plurality of first power lines 120 positioned on the substrate 100; a plurality of second conductive lines 210 positioned on the plurality of first conductive lines 110 and the plurality of first power lines 120; and a plurality of third conductive lines 310 and a plurality of second power lines 320 positioned on the plurality of second conductive lines 210.

The plurality of first conductive lines 110 and the plurality of first power lines 120 may extend in parallel along the first direction DR1. The plurality of second conductive lines 210 may extend in parallel along the second direction DR2.

The second conductive line 210 may include the separation area CUT. The separation area CUT of the second conductive line 210 may overlap at least a portion of the first power line 120. The separation area CUT of the second conductive line 210 may not overlap the boundary of the logic cell LC. The separation areas CUT of the second conductive line 210 may be alternately positioned at a lower side and an upper side based on the boundary of the logic cell LC, and may be disposed in a zigzag form. The separation area CUT of the second conductive line 210 may alternately overlap a lower edge and an upper edge of the first power line 120.

The disposition form of the separation areas CUT of the second conductive line 210 adjacent to the upper edge of the logic cell LC may be different from the disposition form of the separation area CUT of the second conductive line 210 adjacent to the lower edge of the logic cell LC. The disposition form of the separation areas CUT of the second conductive line 210 adjacent to the upper edge of the logic cell LC may be symmetrical to the disposition form of the separation area CUT of the second conductive line 210 adjacent to the lower edge of the logic cell LC. For example, one of the separation areas CUT of the second conductive line 210 positioned at the first column L1 may be disposed under the upper edge of the logic cell LC, and the other thereof may be disposed on the upper edge thereof. One of the separation areas CUT of the second conductive line 210 positioned at the second column L2 may be positioned above the upper edge of the logic cell LC, and the other thereof may be disposed under the upper edge thereof. That is, some of the separation areas CUT of the second conductive line 210 positioned at each column may be disposed under the boundary of the logic cell LC, and the remaining part thereof may be positioned above the boundary of the logic cell LC.

The second conductive line 210 may be connected to the first conductive line 110 at least one of points marked with the first hit point (V1 Hit Point). The first hit point (V1 Hit Point) may be positioned at a point at which the first conductive line 110 and the second conductive line 210 overlap. The first hit point (V1 Hit Point) is not positioned at all points at which the first conductive lines 110 and the second conductive lines 210 overlap. Among the points at which the first conductive lines 110 and the second conductive lines 210 overlap, the first hit point (V1 Hit Point) is not positioned at a point adjacent to the separation area CUT.

In the present embodiment, one second conductive line 210 may overlap five first conductive lines 110 within one logic cell LC. In this case, three or five of the five points at which one second conductive line 210 and five first conductive lines 110 overlap may have the first hit point (V1 hit point). For example, the second conductive line 210 positioned at the first column L1 may have three first hit points (V1 Hit Point) within one logic cell LC. This is because two of the five points at which the second conductive line 210 and the first conductive line 110 positioned at the first column L1 overlap each other are adjacent to the separation area CUT. The second conductive line 210 positioned at the second column L2 may have five first hit points (V1 Hit Point) within one logic cell LC. This is because all of the five points at which the second conductive line 210 and the first conductive line 110 positioned at the second column L2 overlap each other are not adjacent to the separation area CUT.

In the previous embodiment, the number of the first hit points (V1 Hit Point) overlapping the second conductive line 210 positioned at the first column L1 may be the same as the number of the first hit points (V1 Hit Point) overlapping the second conductive line 210 positioned at the second column L2. In the present embodiment, the number of the first hit points (V1 Hit Point) overlapping the second conductive line 210 positioned at the first column L1 may be different from the number of the first hit points (V1 Hit Point) overlapping the second conductive line 210 positioned at the second column L2.

In the present embodiment, by disposing the separation areas CUT in a zigzag form, while sufficiently securing a process margin between the separation area CUT and the first hit point (V1 Hit Point), the number of the first hit points (V1 Hit Points) may be sufficiently provided. The present embodiment is partially different from the previous embodiment in the disposition form of the separation area CUT and the disposition form of the first hit point (V1 Hit Point), but the process margin or the number of the first hit points (V1 Hit Point) may be different from each other.

The plurality of third conductive lines 310 and the plurality of second power lines 320 may extend in parallel along the first direction DR1. Two edges of the logic cell LC facing each other may overlap different second power lines 320, respectively. The plurality of third conductive lines 310 may be positioned between two adjacent second power lines 320.

The third conductive line 310 may be connected to the second conductive line 210 at least one of points marked with the second hit point (V2 Hit Point). The second hit point (V2 Hit Point) may be positioned at a point at which the second conductive line 210 and the third conductive line 310 overlap. The second hit point (V2 Hit Point) is not positioned at all points at which the second conductive lines 210 and the third conductive lines 310 overlap. Among the points at which the second conductive lines 210 and the third conductive lines 310 overlap, the second hit point (V2 Hit Point) is not positioned at a point adjacent to the separation area CUT.

In the present embodiment, one second conductive line 210 may overlap five third conductive lines 310 within one logic cell LC. In this case, three or five of the five points at which one second conductive line 210 and five third conductive lines 310 overlap may have the second hit point (V2 hit point). For example, the second conductive line 210 positioned at the first column L1 may have three second hit points (V2 Hit Point) within one logic cell LC. This is because two of the five points at which the second conductive line 210 and the third conductive line 310 positioned at the first column L1 overlap each other are adjacent to the separation area CUT. The second conductive line 210 positioned at the second column L2 may have five second hit points (V2 Hit Point) within one logic cell LC. This is because all of the five points at which the second conductive line 210 and the third conductive line 310 positioned at the second column L2 overlap each other are not adjacent to the separation area CUT.

In the previous embodiment, the number of the second hit points (V2 Hit Point) overlapping the second conductive line 210 positioned at the first column L1 may be the same as the number of the second hit points (V2 Hit Point) overlapping the second conductive line 210 positioned at the second column L2. In the present embodiment, the number of the second hit points (V2 Hit Point) overlapping the second conductive line 210 positioned at the first column L1 may be different from the number of the second hit points (V2 Hit Point) overlapping the second conductive line 210 positioned at the second column L2.

In the present embodiment, by disposing the separation areas CUT in a zigzag form, while sufficiently securing a process margin between the separation area CUT and the second hit point (V2 Hit Point), the number of the second hit points (V2 Hit Points) may be sufficiently provided. The present embodiment is partially different from the previous embodiment in the disposition form of the separation area CUT and the disposition form of the second hit point (V2 Hit Point), but the process margin or the number of the second hit points (V2 Hit Point) may be different from each other.

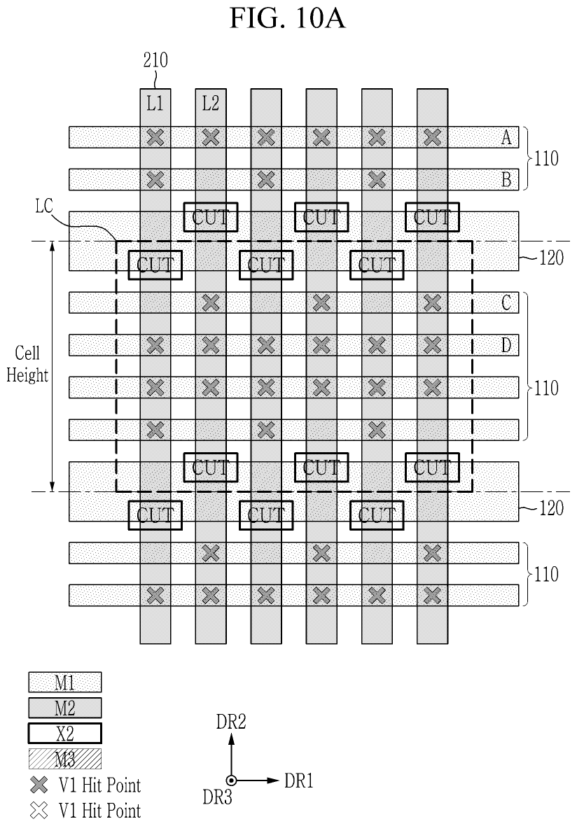

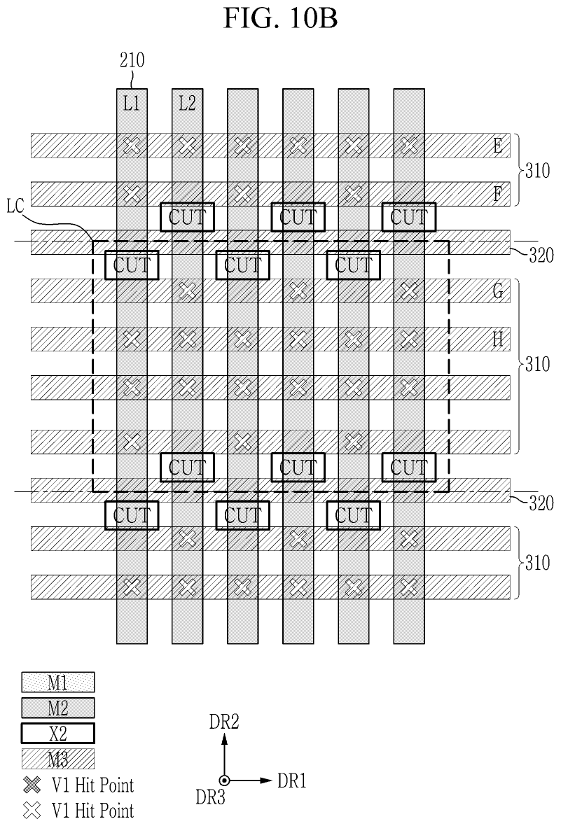

Hereinafter, a semiconductor device according to an embodiment will be described with reference to FIG. 10A and FIG. 10B.

FIG. 10A and FIG. 10B illustrate top plan views of some layers of a semiconductor device according to an embodiment. FIG. 10A illustrates the first conductive layer M1 and the second conductive layer M2, and FIG. 10B illustrates the second conductive layer M2 and the third conductive layer M3.

Since many parts of the embodiment shown in FIG. 10A and FIG. 10B are the same as the embodiment shown in FIG. 1A to FIG. 3, a description thereof will not be repeated and differences will be mainly described. In addition, the same reference numerals are used for components that are the same as those of the previous embodiment. In the present embodiment, the number of the first conductive lines positioned between the first power lines and the number of the third conductive lines positioned between the second power lines are different from those in the previous embodiment.

As shown in FIG. 10A and FIG. 10B, a semiconductor device according to an embodiment includes: a plurality of first conductive lines 110 and a plurality of first power lines 120 positioned on the substrate 100; a plurality of second conductive lines 210 positioned on the plurality of first conductive lines 110 and the plurality of first power lines 120; and a plurality of third conductive lines 310 and a plurality of second power lines 320 positioned on the plurality of second conductive lines 210.

Five first conductive lines 110 may be positioned between two adjacent first power lines 120 in the previous embodiment, while four first conductive lines 110 may be positioned between two adjacent first power lines 120 in the present embodiment. The second conductive line 210 may overlap four first conductive lines 110 within one logic cell LC. In this case, three of four points at which one second conductive line 210 and four first conductive lines 110 overlap may have the first hit point (V1 hit point).

Five third conductive lines 310 may be positioned between two adjacent second power lines 320 in the previous embodiment, while four first conductive lines 310 may be positioned between two adjacent second power lines 320 in the present embodiment. The second conductive line 210 may overlap four third conductive lines 310 within one logic cell LC. In this case, three of four points at which one second conductive line 210 and four third conductive lines 310 overlap may have the second hit point (V2 hit point).

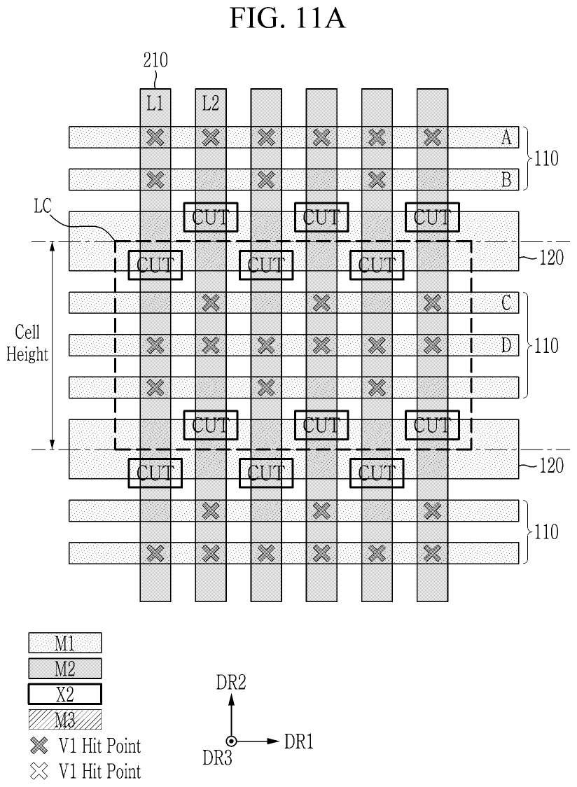

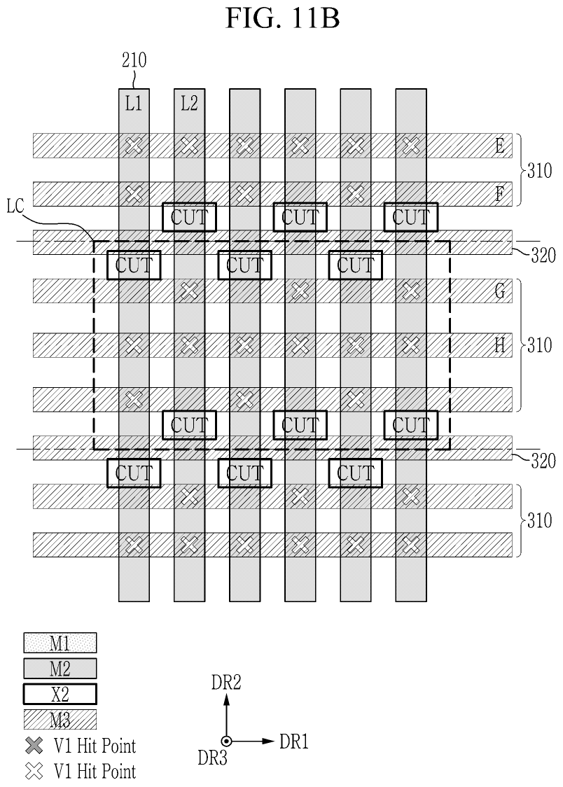

Hereinafter, a semiconductor device according to an embodiment will be described with reference to FIG. 11A and FIG. 11B.

FIG. 11A and FIG. 11B illustrate top plan views of some layers of a semiconductor device according to an embodiment. FIG. 11A illustrates the first conductive layer M1 and the second conductive layer M2, and FIG. 11B illustrates the second conductive layer M2 and the third conductive layer M3.

Since many parts of the embodiment shown in FIG. 11A and FIG. 11B are the same as the embodiment shown in FIG. 1A to FIG. 3, a description thereof will not be repeated and differences will be mainly described. In addition, the same reference numerals are used for components that are the same as those of the previous embodiment. In the present embodiment, the number of the first conductive lines positioned between the first power lines and the number of the third conductive lines positioned between the second power lines are different from those in the previous embodiment.

As shown in FIG. 11A and FIG. 11B, a semiconductor device according to an embodiment includes: a plurality of first conductive lines 110 and a plurality of first power lines 120 positioned on the substrate 100; a plurality of second conductive lines 210 positioned on the plurality of first conductive lines 110 and the plurality of first power lines 120; and a plurality of third conductive lines 310 and a plurality of second power lines 320 positioned on the plurality of second conductive lines 210.

Five first conductive lines 110 may be positioned between two adjacent first power lines 120 in the previous embodiment, while three first conductive lines 110 may be positioned between two adjacent first power lines 120 in the present embodiment. The second conductive line 210 may overlap three first conductive lines 110 within one logic cell LC. In this case, two of three points at which one second conductive line 210 and three first conductive lines 110 overlap may have the first hit point (V1 hit point).

Five third conductive lines 310 may be positioned between two adjacent second power lines 320 in the previous embodiment, while three first conductive lines 310 may be positioned between two adjacent second power lines 320 in the present embodiment. The second conductive line 210 may overlap three third conductive lines 310 within one logic cell LC. In this case, two of three points at which one second conductive line 210 and three third conductive lines 310 overlap may have the second hit point (V2 hit point).

However, the number of the first conductive lines 110 positioned between the first power lines 120 and the number of the third conductive lines 310 positioned between the second power lines 320 are not limited thereto, and may be variously changed. For example, the number of the first conductive lines 110 positioned between the first power lines 120 may be 6 or more, and the number of the third conductive lines 310 positioned between the second power lines 320 may be 6 or more.

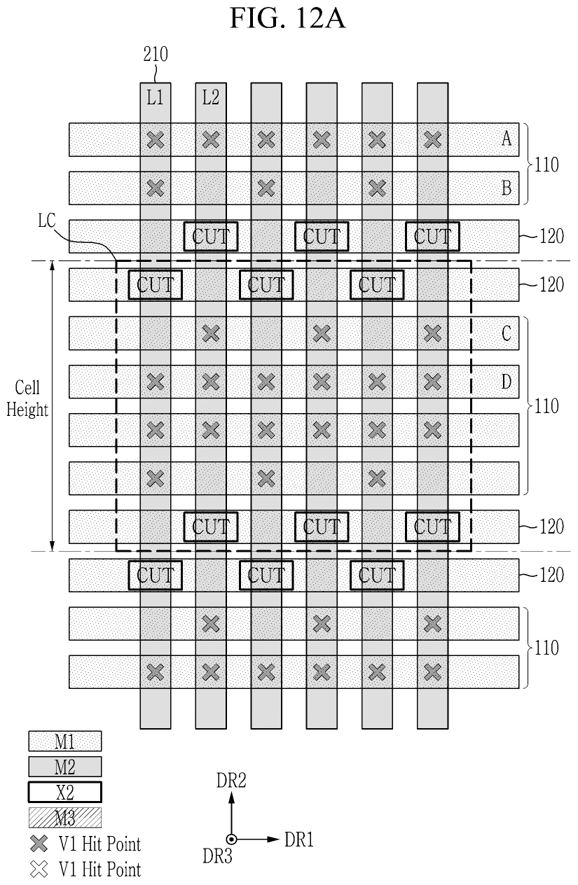

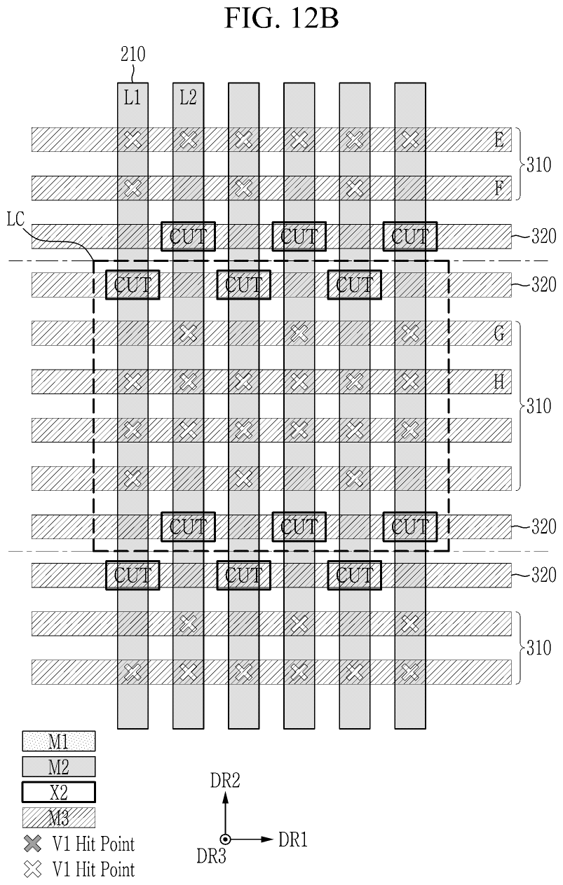

Hereinafter, a semiconductor device according to an embodiment will be described with reference to FIG. 12A and FIG. 12B.

FIG. 12A and FIG. 12B illustrate top plan views of some layers of a semiconductor device according to an embodiment. FIG. 12A illustrates the first conductive layer M1 and the second conductive layer M2, and FIG. 12B illustrates the second conductive layer M2 and the third conductive layer M3.

Since many parts of the embodiment shown in FIG. 12A and FIG. 12B are the same as the embodiment shown in FIG. 10A and FIG. 10B, a description thereof will not be repeated and differences will be mainly described. In addition, the same reference numerals are used for components that are the same as those of the previous embodiment. In the present embodiment, the number of the first power lines and the number of the second power lines are different from those of the previous embodiment.

As shown in FIG. 12A and FIG. 12B, a semiconductor device according to an embodiment includes: a plurality of first conductive lines 110 and a plurality of first power lines 120 positioned on the substrate 100; a plurality of second conductive lines 210 positioned on the plurality of first conductive lines 110 and the plurality of first power lines 120; and a plurality of third conductive lines 310 and a plurality of second power lines 320 positioned on the plurality of second conductive lines 210.

In the previous embodiment, the first power line 120 may be wider than the first conductive line 110, and one first power line 120 may be positioned at the boundary of the logic cell LC. In the present embodiment, the first power line 120 may have a similar width to that of the first conductive line 110. The width of the first power line 120 may be substantially the same as the width of the first conductive line 110. The first power line 120 may not overlap the boundary of the logic cell LC. Different first power lines 120 may be positioned at upper and lower sides based on the boundary of the logic cell LC. In this embodiment, the number of the first power lines 120 may be about twice that of the previous embodiment.

The separation area CUT of the second conductive line 210 may alternately overlap the first power line 120 positioned at the lower side based on the boundary of the logic cell LC and the first power line 120 positioned at the upper side based on the boundary of the logic cell LC.

The second conductive line 210 may overlap four first conductive lines 110 within one logic cell LC. In this case, three of four points at which one second conductive line 210 and four first conductive lines 110 overlap may have the first hit point (V1 hit point).

In the previous embodiment, the second power line 320 may overlap the boundary of the logic cell LC. In the present embodiment, the second power line 320 may not overlap the boundary of the logic cell LC. Different second power lines 320 may be positioned at the upper and lower sides based on the boundary of the logic cell LC. In the present embodiment, the number of the second power lines 320 may be about twice that of the previous embodiment.

The separation area CUT of the second conductive line 210 may alternately overlap the second power line 320 positioned at the lower side based on the boundary of the logic cell LC and the second power line 320 positioned at the upper side based on the boundary of the logic cell LC.

The second conductive line 210 may overlap four third conductive lines 310 within one logic cell LC. In this case, three of four points at which one second conductive line 210 and four third conductive lines 310 overlap may have the first hit point (V1 hit point).

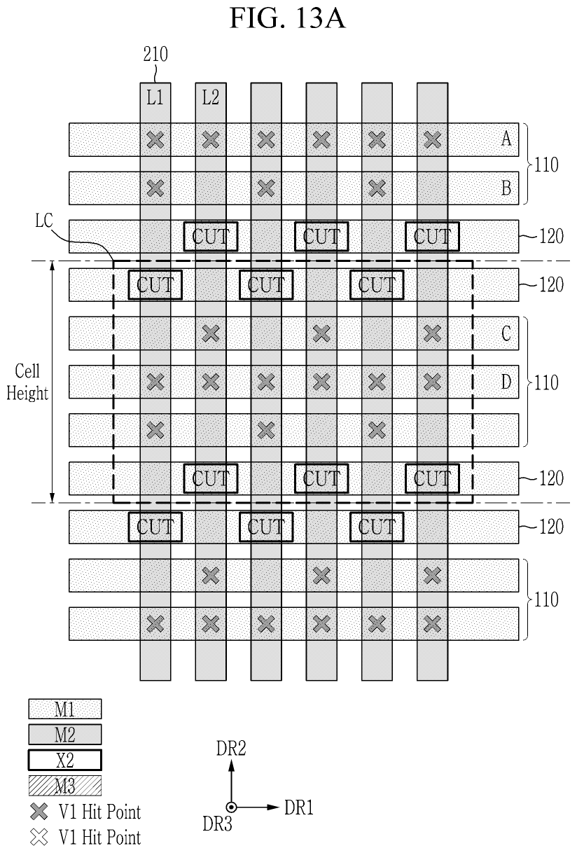

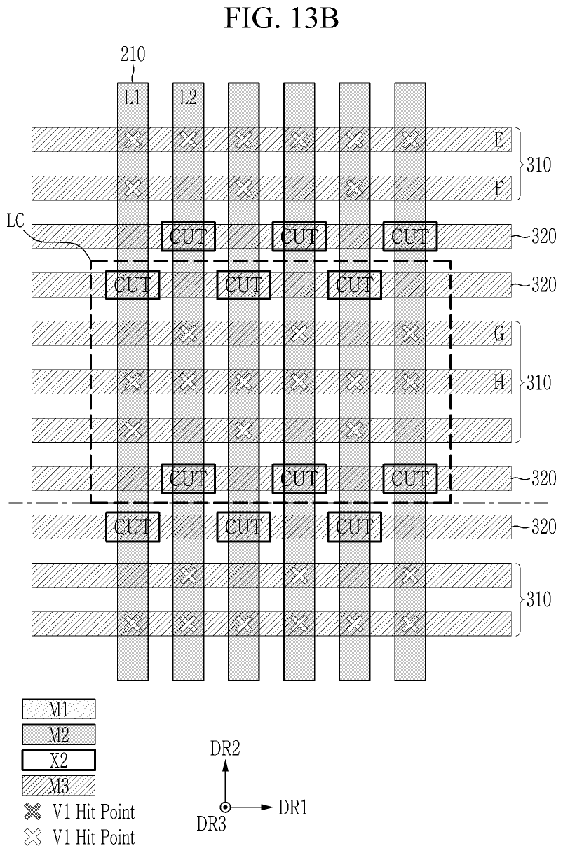

Hereinafter, a semiconductor device according to an embodiment will be described with reference to FIG. 13A and FIG. 13B.

FIG. 13A and FIG. 13B illustrate top plan views of some layers of a semiconductor device according to an embodiment. FIG. 13A illustrates the first conductive layer M1 and the second conductive layer M2, and FIG. 13B illustrates the second conductive layer M2 and the third conductive layer M3.

Since many parts of the embodiment shown in FIG. 13A and FIG. 13B are the same as the embodiment shown in FIG. 12A and FIG. 12B, a description thereof will not be repeated and differences will be mainly described. In addition, the same reference numerals are used for components that are the same as those of the previous embodiment. In the present embodiment, the number of the first conductive lines and the number of the third conductive lines positioned within one logic cell are different from those of the previous embodiment.

As shown in FIG. 13A and FIG. 13B, a semiconductor device according to an embodiment includes: a plurality of first conductive lines 110 and a plurality of first power lines 120 positioned on the substrate 100; a plurality of second conductive lines 210 positioned on the plurality of first conductive lines 110 and the plurality of first power lines 120; and a plurality of third conductive lines 310 and a plurality of second power lines 320 positioned on the plurality of second conductive lines 210.

Four first conductive lines 110 may be positioned within one logic cell LC in the previous embodiment, and three first conductive lines 110 may be positioned within one logic cell LC in the present embodiment. The second conductive line 210 may overlap three first conductive lines 110 within one logic cell LC. In this case, two of three points at which one second conductive line 210 and three first conductive lines 110 overlap may have the first hit point (V1 hit point).

Four third conductive lines 310 may be positioned within one logic cell LC in the previous embodiment, and three third conductive lines 310 may be positioned within one logic cell LC in the present embodiment. The second conductive line 210 may overlap three third conductive lines 310 within one logic cell LC. In this case, two of three points at which one second conductive line 210 and three third conductive lines 310 overlap may have the second hit point (V2 hit point).

However, the number of the first conductive lines 110 and the number of the third conductive lines 310 positioned within one logic cell LC are not limited thereto, and may be variously changed. For example, the number of the first conductive lines 110 positioned within one logic cell LC may be 6 or more, and the number of the third conductive lines 310 positioned within one logic cell LC may be 6 or more.

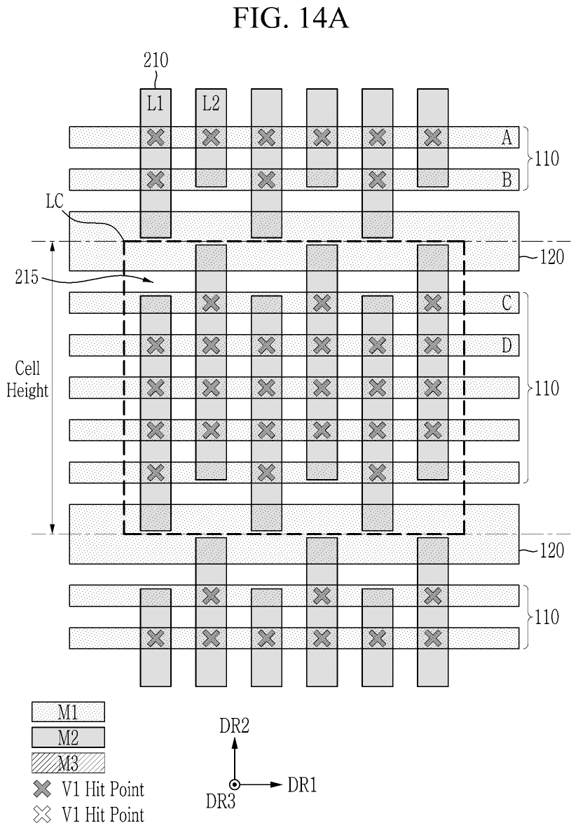

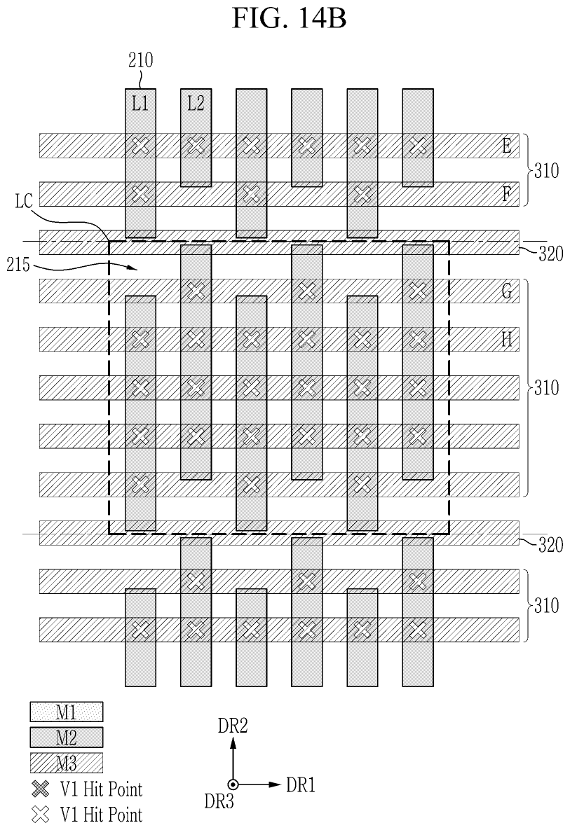

Hereinafter, a semiconductor device according to an embodiment will be described with reference to FIG. 14A and FIG. 14B.

FIG. 14A and FIG. 14B illustrate top plan views of some layers of a semiconductor device according to an embodiment. FIG. 14A illustrates the first conductive layer M1 and the second conductive layer M2, and FIG. 14B illustrates the second conductive layer M2 and the third conductive layer M3.

Since many parts of the embodiment shown in FIG. 14A and FIG. 14B are the same as the embodiment shown in FIG. 1A to FIG. 3, a description thereof will not be repeated and differences will be mainly described. In addition, the same reference numerals are used for components that are the same as those of the previous embodiment. The present embodiment is different from the previous embodiment in that the separation area of the second conductive line is formed without performing an additional process.

In the previous embodiment, the second conductive line 210 is formed as a single wire connected along the second direction DR2, and then by removing at least a portion of the second conductive line 210 through an additional process, the separation area CUT may be formed. In the present embodiment, the second conductive line 210 is not formed as a single wire connected along the second direction DR2. In the step of forming the second conductive line 210, the second conductive lines 210 positioned on an imaginary line extending along the second direction DR2 may be formed to be separated from each other. Accordingly, an additional process for forming the separation area 215 in which adjacent second conductive lines 210 are separated from each other along the second direction DR2 is not required.

The second conductive line 210 positioned in one column may include a plurality of separation areas 215. For example, the second conductive line 210 may be separated around the boundary of the logic cell LC. That is, the separation area 215 of the second conductive line 210 may be positioned to be adjacent to the boundary of the logic cell LC. The separation area 215 of the second conductive line 210 may overlap at least a portion of the first power line 120. The separation area 215 of the second conductive line 210 may overlap the boundary of the logic cell LC. The separation areas 215 of the second conductive line 210 may be alternately positioned at a lower side and an upper side based on the boundary of the logic cell LC, and may be disposed in a zigzag form. The separation area 215 of the second conductive line 210 may alternately overlap a lower edge and an upper edge of the first power line 120.

The disposition form of the separation areas 215 of the second conductive line 210 adjacent to the upper edge of the logic cell LC may be substantially the same as the disposition form of the separation areas 215 of the second conductive line 210 adjacent to the lower edge of the logic cell LC. For example, all of the separation areas 215 of the second conductive line 210 positioned at the first column L1 may be positioned at the lower side based on the boundary of the logic cell LC. All of the separation areas 215 of the second conductive line 210 positioned at the second column L2 may be positioned at the upper side based on the boundary of the logic cell LC.

The second conductive line 210 may be connected to the first conductive line 110 at least one of points marked with the first hit point (V1 Hit Point). The first hit point (V1 Hit Point) may be positioned at a point at which the first conductive line 110 and the second conductive line 210 overlap. The first hit point (V1 Hit Point) is not positioned at all points at which the first conductive lines 110 and the second conductive lines 210 overlap. Among the points at which the first conductive lines 110 and the second conductive lines 210 overlap, the first hit point (V1 Hit Point) is not positioned at a point adjacent to the separation area 215.

In the present embodiment, one second conductive line 210 may overlap five first conductive lines 110 within one logic cell LC. In this case, four of the five points at which the one second conductive line 210 and the five first conductive lines 110 overlap may have the first hit point (V1 hit point).

In the present embodiment, by disposing the separation areas 215 of the second conductive line 210 in a zigzag form, while sufficiently securing a process margin between the separation area 215 and the first hit point (V1 Hit Point), the number of the first hit points (V1 Hit Points) may be sufficiently provided. As described above, as the process margin between the separation area 215 and the first hit point (V1 Hit Point) is sufficiently secured, the separation area 215 may not be formed through a separate process. That is, the second conductive line 210 having the separation area 215 may be formed through one process without using a separate mask for the separation area 215 and performing a separate process. Accordingly, the number of masks used in a process of manufacturing a semiconductor device may be reduced, and a process time and cost may be reduced.

The third conductive line 310 may be connected to the second conductive line 210 at least one of points marked with the second hit point (V2 Hit Point). The second hit point (V2 Hit Point) may be positioned at a point at which the second conductive line 210 and the third conductive line 310 overlap. The second hit point (V2 Hit Point) is not positioned at all points at which the second conductive lines 210 and the third conductive lines 310 overlap. Among the points at which the second conductive lines 210 and the third conductive lines 310 overlap, the second hit point (V2 Hit Point) is not positioned at a point adjacent to the separation area 215.

In the present embodiment, one second conductive line 210 may overlap five third conductive lines 310 within one logic cell LC. In this case, four of the five points at which the one second conductive line 210 and the five third conductive lines 310 overlap may have the second hit point (V2 Hit Point).

In the present embodiment, by disposing the separation areas 215 in a zigzag form, while sufficiently securing a process margin between the separation area 215 and the second hit point (V2 Hit Point), the number of the second hit points (V2 Hit Points) may be sufficiently provided. As described above, as the process margin between the separation area 215 and the second hit point (V2 Hit Point) is sufficiently secured, the separation area 215 may not be formed through a separate process. Accordingly, the number of masks used in a process of manufacturing a semiconductor device may be reduced, and a process time and cost may be reduced.

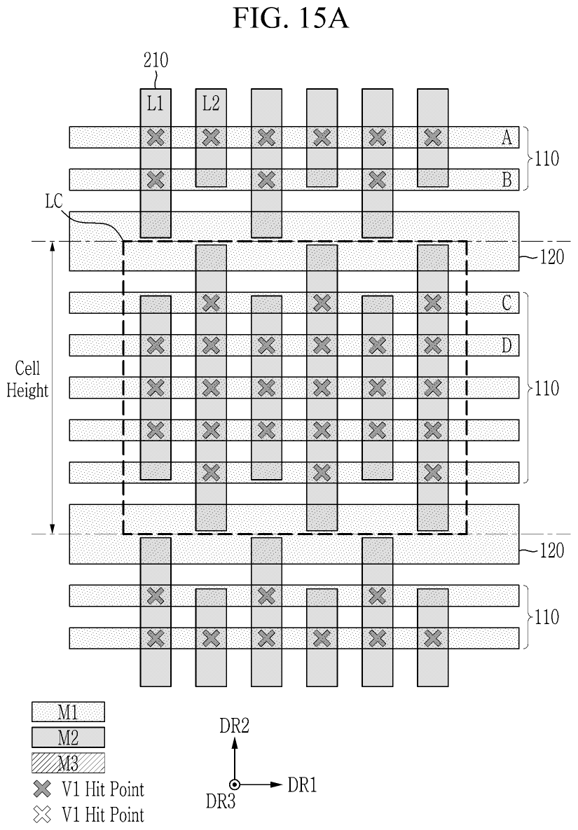

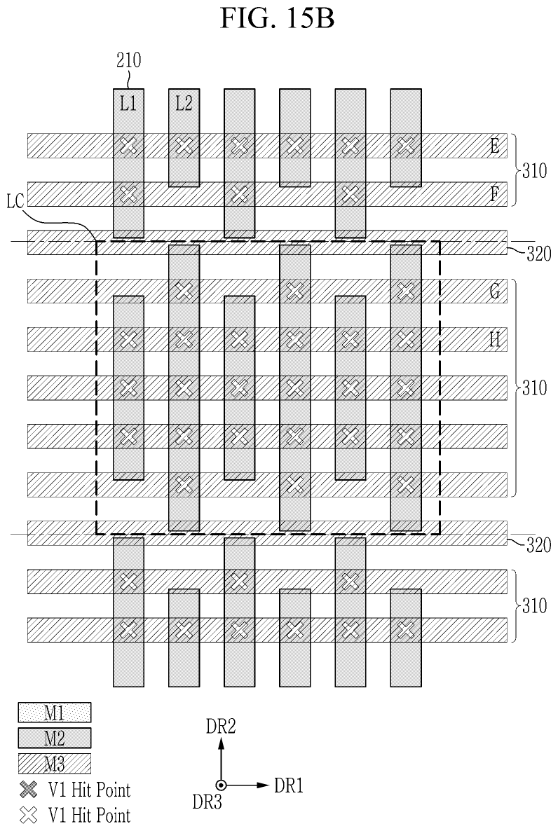

Hereinafter, a semiconductor device according to an embodiment will be described with reference to FIG. 15A and FIG. 15B.

FIG. 15A and FIG. 15B illustrate top plan views of some layers of a semiconductor device according to an embodiment. FIG. 15A illustrates the first conductive layer M1 and the second conductive layer M2, and FIG. 15B illustrates the second conductive layer M2 and the third conductive layer M3.

Since many parts of the embodiment shown in FIG. 15A and FIG. 15B are the same as the embodiment shown in FIG. 14A and FIG. 14B, a description thereof will not be repeated and differences will be mainly described. In addition, the same reference numerals are used for components that are the same as those of the previous embodiment. In the present embodiment, the disposition form of the separation area of the second conductive line is partially different from that of the previous embodiment.

The disposition form of the separation areas 215 of the second conductive line 210 adjacent to the upper edge of the logic cell LC may be different from the disposition form of the separation areas 215 of the second conductive line 210 adjacent to the lower edge of the logic cell LC. The disposition form of the separation areas 215 of the second conductive line 210 adjacent to the upper edge of the logic cell LC may be symmetrical to the disposition form of the separation areas 215 of the second conductive line 210 adjacent to the lower edge of the logic cell LC. For example, one of the separation areas 215 of the second conductive line 210 positioned at the first column L1 may be disposed under the upper edge of the logic cell LC, and the other thereof may be disposed on the upper edge thereof. One of the separation areas 215 of the second conductive line 210 positioned at the second column L2 may be positioned above the upper edge of the logic cell LC, and the other thereof may be disposed under the upper edge thereof. That is, some of the separation areas 215 of the second conductive line 210 positioned at each column may be disposed under the boundary of the logic cell LC, and the remaining part thereof may be positioned above the boundary of the logic cell LC.

In the present embodiment, one second conductive line 210 may overlap five first conductive lines 110 within one logic cell LC. In this case, three or five of the five points at which one second conductive line 210 and five first conductive lines 110 overlap may have the first hit point (V1 hit point).

In the present embodiment, one second conductive line 210 may overlap five third conductive lines 310 within one logic cell LC. In this case, three or five of the five points at which one second conductive line 210 and five third conductive lines 310 overlap may have the second hit point (V2 hit point).

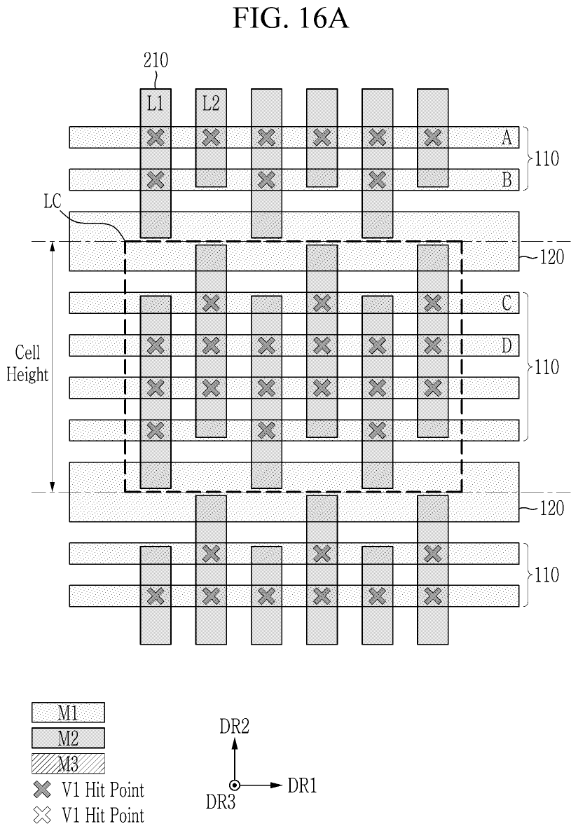

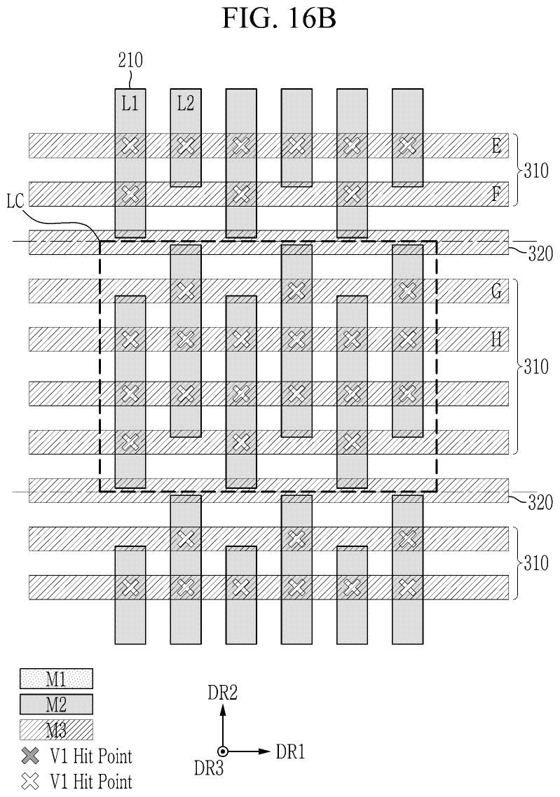

Hereinafter, a semiconductor device according to an embodiment will be described with reference to FIG. 16A and FIG. 16B.

FIG. 16A and FIG. 16B illustrate top plan views of some layers of a semiconductor device according to an embodiment. FIG. 16A illustrates the first conductive layer M1 and the second conductive layer M2, and FIG. 16B illustrates the second conductive layer M2 and the third conductive layer M3.

Since many parts of the embodiment shown in FIG. 16A and FIG. 16B are the same as the embodiment shown in FIG. 14A and FIG. 14B, a description thereof will not be repeated and differences will be mainly described. In addition, the same reference numerals are used for components that are the same as those of the previous embodiment. In the present embodiment, the number of the first conductive lines positioned between the first power lines and the number of the third conductive lines positioned between the second power lines are different from those in the previous embodiment.

Five first conductive lines 110 may be positioned between two adjacent first power lines 120 in the previous embodiment, while four first conductive lines 110 may be positioned between two adjacent first power lines 120 in the present embodiment. The second conductive line 210 may overlap four first conductive lines 110 within one logic cell LC. In this case, three of four points at which one second conductive line 210 and four first conductive lines 110 overlap may have the first hit point (V1 hit point).

Five third conductive lines 310 may be positioned between two adjacent second power lines 320 in the previous embodiment, while four first conductive lines 310 may be positioned between two adjacent second power lines 320 in the present embodiment. The second conductive line 210 may overlap four third conductive lines 310 within one logic cell LC. In this case, three of four points at which one second conductive line 210 and four third conductive lines 310 overlap may have the second hit point (V2 hit point).

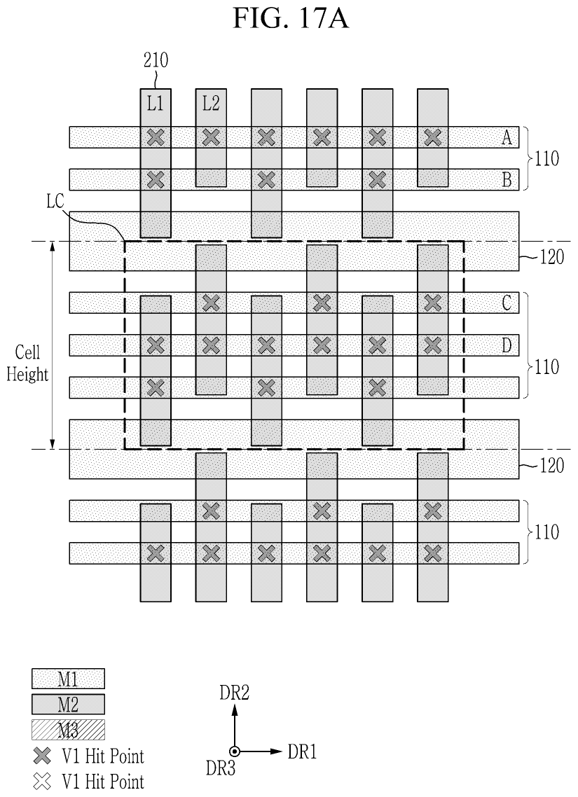

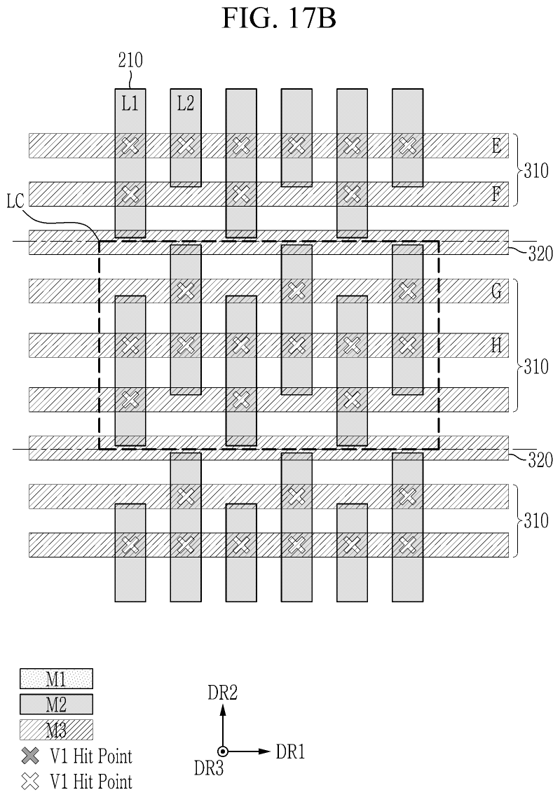

Hereinafter, a semiconductor device according to an embodiment will be described with reference to FIG. 17A and FIG. 17B.

FIG. 17A and FIG. 17B illustrate top plan views of some layers of a semiconductor device according to an embodiment. FIG. 17A illustrates the first conductive layer M1 and the second conductive layer M2, and FIG. 17B illustrates the second conductive layer M2 and the third conductive layer M3.

Since many parts of the embodiment shown in FIG. 17A and FIG. 17B are the same as the embodiment shown in FIG. 14A and FIG. 14B, a description thereof will not be repeated and differences will be mainly described. In addition, the same reference numerals are used for components that are the same as those of the previous embodiment. In the present embodiment, the number of the first conductive lines positioned between the first power lines and the number of the third conductive lines positioned between the second power lines are different from those in the previous embodiment.

Five first conductive lines 110 may be positioned between two adjacent first power lines 120 in the previous embodiment, while three first conductive lines 110 may be positioned between two adjacent first power lines 120 in the present embodiment. The second conductive line 210 may overlap three first conductive lines 110 within one logic cell LC. In this case, two of three points at which one second conductive line 210 and three first conductive lines 110 overlap may have the first hit point (V1 hit point).

Five third conductive lines 310 may be positioned between two adjacent second power lines 320 in the previous embodiment, while three first conductive lines 310 may be positioned between two adjacent second power lines 320 in the present embodiment. The second conductive line 210 may overlap three third conductive lines 310 within one logic cell LC. In this case, two of three points at which one second conductive line 210 and three third conductive lines 310 overlap may have the second hit point (V2 hit point).

However, the number of the first conductive lines 110 positioned between the first power lines 120 and the number of the third conductive lines 310 positioned between the second power lines 320 are not limited thereto, and may be variously changed. For example, the number of the first conductive lines 110 positioned between the first power lines 120 may be 6 or more, and the number of the third conductive lines 310 positioned between the second power lines 320 may be 6 or more.

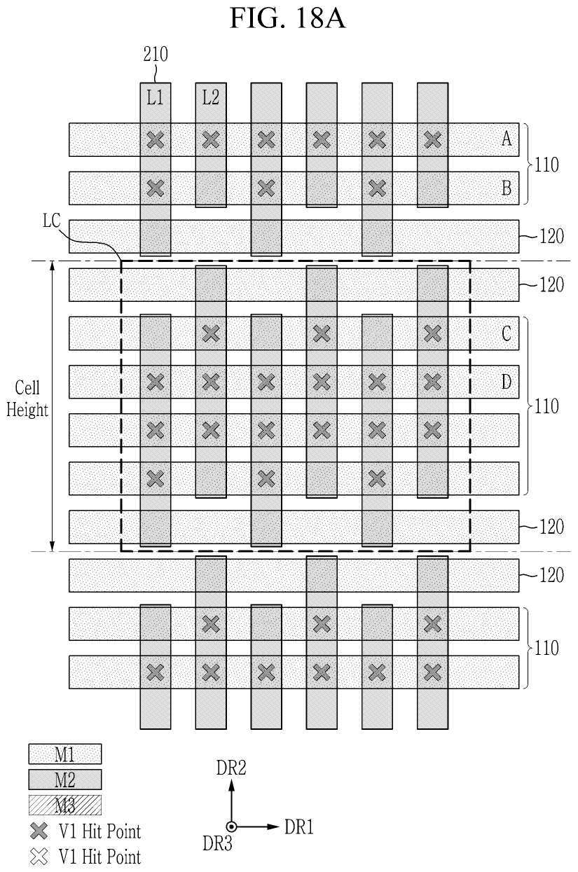

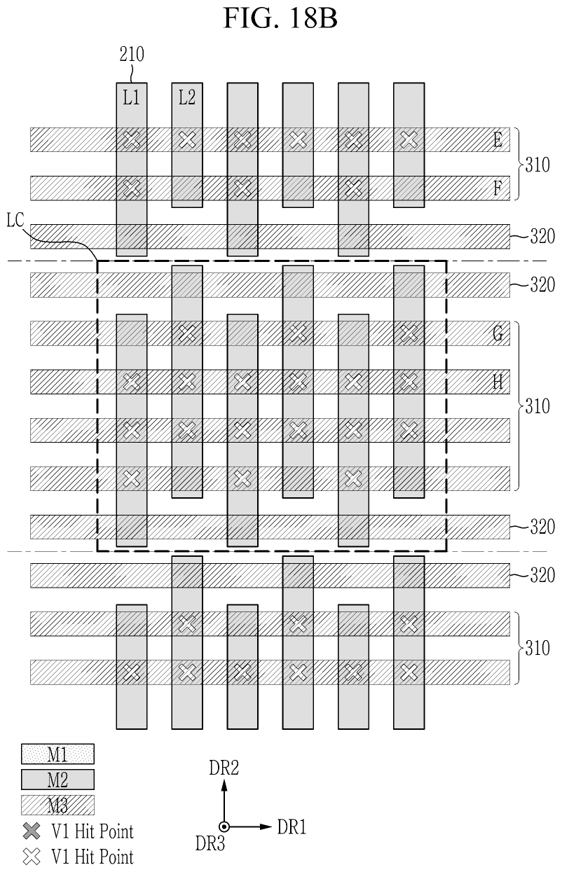

Hereinafter, a semiconductor device according to an embodiment will be described with reference to FIG. 18A and FIG. 18B.

FIG. 18A and FIG. 18B illustrate top plan views of some layers of a semiconductor device according to an embodiment. FIG. 18A illustrates the first conductive layer M1 and the second conductive layer M2, and FIG. 18B illustrates the second conductive layer M2 and the third conductive layer M3.

Since many parts of the embodiment shown in FIG. 18A and FIG. 18B are the same as the embodiment shown in FIG. 16A and FIG. 16B, a description thereof will not be repeated and differences will be mainly described. In addition, the same reference numerals are used for components that are the same as those of the previous embodiment. In the present embodiment, the number of the first power lines and the number of the second power lines are different from those of the previous embodiment.

In the previous embodiment, the first power line 120 may be wider than the first conductive line 110, and one first power line 120 may be positioned at the boundary of the logic cell LC. In the present embodiment, the first power line 120 may have a width similar to that of the first conductive line 110. The width of the first power line 120 may be substantially the same as the width of the first conductive line 110. The first power line 120 may not overlap the boundary of the logic cell LC. Different first power lines 120 may be positioned at upper and lower sides based on the boundary of the logic cell LC. In this embodiment, the number of the first power lines 120 may be about twice that of the previous embodiment.

The separation area 215 of the second conductive line 210 may alternately overlap the first power line 120 positioned at the lower side based on the boundary of the logic cell LC and the first power line 120 positioned at the upper side based on the boundary of the logic cell LC.

The second conductive line 210 may overlap four first conductive lines 110 within one logic cell LC. In this case, three of four points at which one second conductive line 210 and four first conductive lines 110 overlap may have the first hit point (V1 hit point).

In the previous embodiment, the second power line 320 may overlap the boundary of the logic cell LC. In the present embodiment, the second power line 320 may not overlap the boundary of the logic cell LC. Different second power lines 320 may be positioned at the upper and lower sides based on the boundary of the logic cell LC. In the present embodiment, the number of the second power lines 320 may be about twice that of the previous embodiment.

The separation area 215 of the second conductive line 210 may alternately overlap the second power line 320 positioned at the lower side based on the boundary of the logic cell LC and the second power line 320 positioned at the upper side based on the boundary of the logic cell LC.

The second conductive line 210 may overlap four third conductive lines 310 within one logic cell LC. In this case, three of four points at which one second conductive line 210 and four third conductive lines 310 overlap may have the first hit point (V1 hit point).

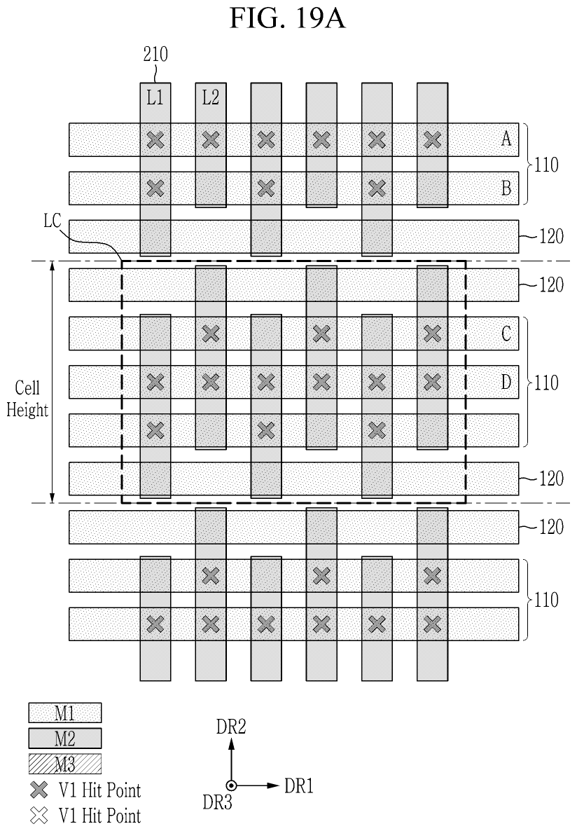

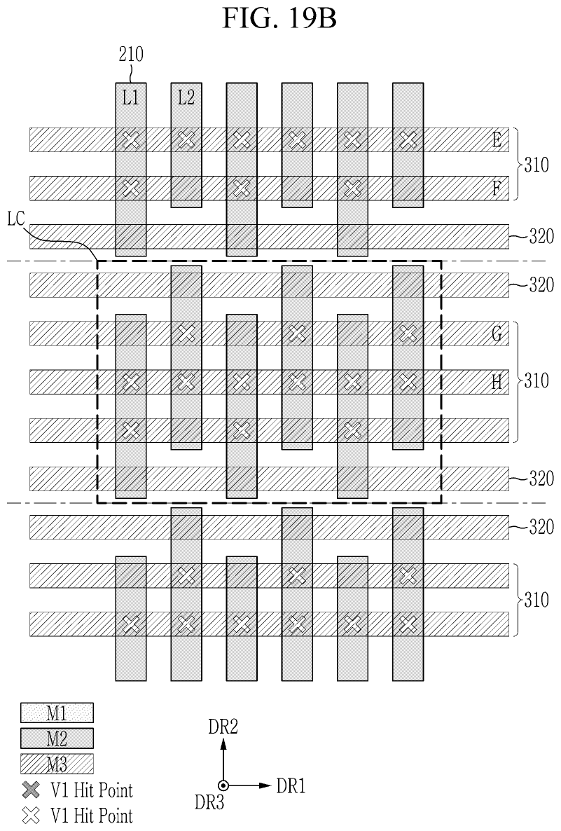

Hereinafter, a semiconductor device according to an embodiment will be described with reference to FIG. 19A and FIG. 19B.

FIG. 19A and FIG. 19B illustrate top plan views of some layers of a semiconductor device according to an embodiment. FIG. 19A illustrates the first conductive layer M1 and the second conductive layer M2, and FIG. 19B illustrates the second conductive layer M2 and the third conductive layer M3.

Since many parts of the embodiment shown in FIG. 19A and FIG. 19B are the same as the embodiment shown in FIG. 18A and FIG. 18B, a description thereof will not be repeated and differences will be mainly described. In addition, the same reference numerals are used for components that are the same as those of the embodiment. In the present embodiment, the number of the first conductive lines and the number of the third conductive lines positioned within one logic cell are different from those of the previous embodiment.

Four first conductive lines 110 may be positioned within one logic cell LC in the previous embodiment, and three first conductive lines 110 may be positioned within one logic cell LC in the present embodiment. The second conductive line 210 may overlap three first conductive lines 110 within one logic cell LC. In this case, two of three points at which one second conductive line 210 and three first conductive lines 110 overlap may have the first hit point (V1 hit point).

Four third conductive lines 310 may be positioned within one logic cell LC in the previous embodiment, and three third conductive lines 310 may be positioned within one logic cell LC in the present embodiment. The second conductive line 210 may overlap three third conductive lines 310 within one logic cell LC. In this case, two of three points at which one second conductive line 210 and three third conductive lines 310 overlap may have the second hit point (V2 hit point).

The number of the first conductive lines 110 and the number of the third conductive lines 310 positioned within one logic cell LC are not limited thereto, and may be variously changed. For example, the number of the first conductive lines 110 positioned within one logic cell LC may be 6 or more, and the number of the third conductive lines 310 positioned within one logic cell LC may be 6 or more.

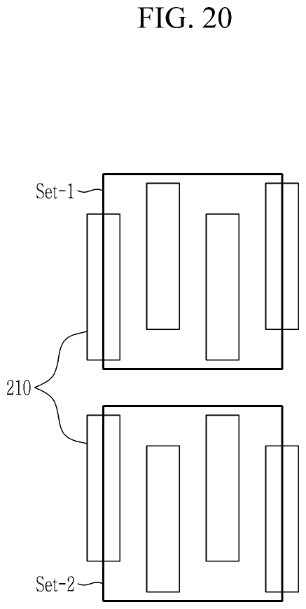

Hereinafter, a disposition form of a plurality of cells included in a semiconductor device according to an embodiment will be described with reference to FIG. 20 to FIG. 22.

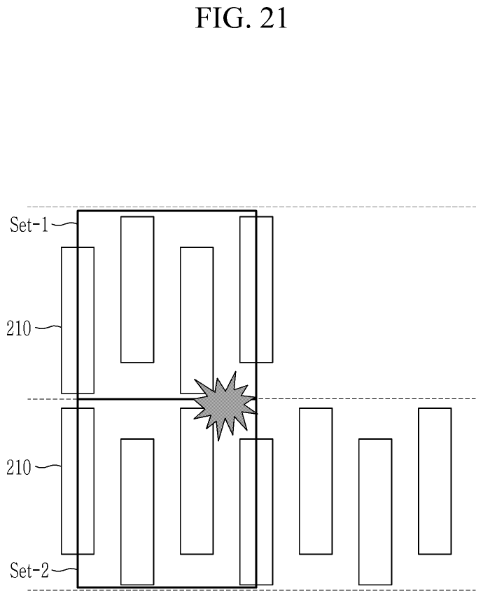

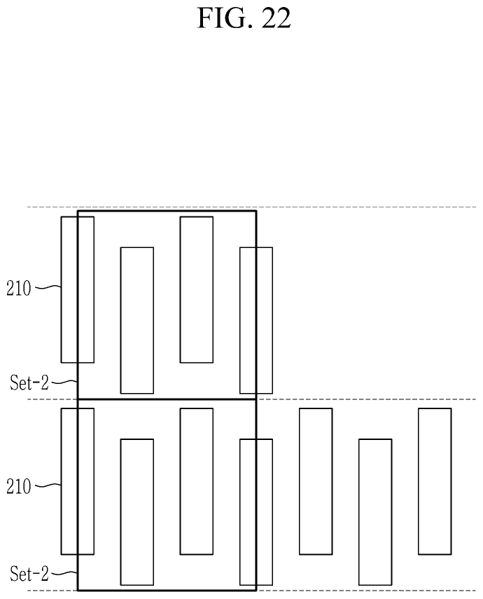

FIG. 20 illustrates two types of cells configuring a semiconductor device according to an embodiment, and FIG. 21 and FIG. 22 illustrate disposition forms of a plurality of cells configuring a semiconductor device according to an embodiment. In FIG. 20 to FIG. 22, the second conductive line is shown, and for convenience, wires positioned in the first conductive layer and the third conductive layer are omitted from the illustration.

As shown in FIG. 20, a logic cell configuring a semiconductor device according to an embodiment may include two types (Set-1 and Set-2). Within the logic cells of two types (Set-1 and Set-2), the second conductive line 210 may be disposed in a zigzag form. The separation areas in which the second conductive lines 210 are separated are disposed so as to be alternately biased to the lower side and the upper side based on the boundary of the logic cell. The disposition shape of the second conductive line 210 in the logic cell of the first type (Set-1) may be symmetrical to the disposition shape of the second conductive line 210 in the logic cell of the second type (Set-2). For example, the second conductive lines 210 positioned at the first and third columns within the logic cell of the first type (Set-1) may be disposed to be closer to the lower edge of the logic cell. The second conductive lines 210 positioned at the second and fourth columns within the logic cell of the first type (Set-1) may be disposed to be closer to the upper edge of the logic cell. The second conductive lines 210 positioned at the first and third columns within the logic cell of the second type (Set-2) may be disposed to be closer to the upper edge of the logic cell. The second conductive lines 210 positioned at the second and fourth columns within the logic cell of the second type (Set-2) may be disposed to be closer to the lower edge of the logic cell.

As shown in FIG. 21, when the logic cells of the first type (Set-1) and the logic cells of the second type (Set-2) are disposed so as to be vertically adjacent to each other, conflict may occur between the adjacent logic cells. For example, the process margin between the second conductive line 210 positioned at the third column of the logic cell of the first type (Set-1) and the second conductive line 210 positioned at the third column of the logic cell of the second type (Set-2) may be insufficient, and a short-circuit may occur.

As shown in FIG. 22, the conflict between the adjacent logic cells can be prevented by vertically disposing the logic cells of the second type (Set-2). That is, the process margin between the adjacent second conductive lines 210 may be sufficiently secured.

As described above, by providing the logic cells of the two types (Set-1 and Set-2) and properly disposing the logic cells of the two types (Set-1 and Set-2), the conflict between the adjacent logic cells may be prevented.

By way of summation and review, embodiments may provide a semiconductor device that can sufficiently secure a process margin between wires. An embodiment may provide a semiconductor device that includes a plurality of logic cells, each of the plurality of logic cell including a plurality of first conductive lines and a plurality of first power lines. A plurality of second conductive lines may be disposed on the plurality of first conductive lines and the plurality of first power lines. A plurality of third conductive lines and a plurality of second power lines may be disposed on the plurality of second conductive lines. The first conductive line, the first power line, the third conductive line, and the second power line may extend in a first direction. The second conductive line may extend in a second direction crossing the first direction. The second conductive line may include a separation area disposed adjacent to a boundary of the logic cell. The separation areas of the second conductive line may be alternately positioned at a lower side and an upper side based on the boundary of the logic cell to be disposed in a zigzag form. Points at which the first conductive lines and the second conductive lines overlap may have first hit points to which the first conductive lines and the second conductive lines are able to be connected, except for a point that is adjacent to the separation area of the second conductive line.

Points at which the second conductive lines and the third conductive lines overlap may have second hit points to which the second conductive lines and the third conductive lines are able to be connected, except for a point that is adjacent to the separation area of the second conductive line.

The first power line may overlap the boundary of the logic cell, and the separation areas of the second conductive line may alternately overlap a lower edge and an upper edge of the first power line to be disposed in a zigzag form.

A width of the first power line may be wider than that of the first conductive line.

The second power line may overlap the boundary of the logic cell, and the separation areas of the second conductive line may be alternately positioned at a lower side and an upper side based on the second power line to be disposed in a zigzag form.

A width of the second power line may be substantially the same as that of the third conductive line.

A disposition form of the separation areas of the second conductive line adjacent to the upper edge of the logic cell and a disposition form of the separation areas of the second conductive line adjacent to the lower edge of the logic cell may be substantially the same.

The number of first hit points overlapping the second conductive line positioned at a first column may be substantially the same as the number of first hit points overlapping the second conductive line positioned at a second column, and the number of second hit points overlapping the second conductive line positioned at the first column may be substantially the same as the number of second hit points overlapping the second conductive line positioned at the second column.

Within one logic cell, each of the plurality of second conductive lines may overlap five first conductive lines and five third conductive lines, and each of the plurality of second conductive lines may overlap four first hit points and four second hit points.

A disposition form of the separation areas of the second conductive line adjacent to the upper edge of the logic cell and a disposition form of the separation areas of the second conductive line adjacent to the lower edge of the logic cell may be symmetrical to each other.

The number of first hit points overlapping the second conductive line positioned at a first column may be different from the number of first hit points overlapping the second conductive line positioned at a second column, and the number of second hit points overlapping the second conductive line positioned at the first column may be different from the number of second hit points overlapping the second conductive line positioned at the second column.

Within one logic cell, each of the plurality of second conductive lines may overlap five first conductive lines and five third conductive lines, some of the plurality of second conductive lines may overlap three first hit points and three second hit points, and the remainder of the plurality of second conductive lines may overlap five first hit points and five second hit points.

The first power line may be positioned at upper and lower sides based on the boundary of the logic cell, respectively; the separation areas of the second conductive line may alternately overlap the first power line positioned at the lower side of the boundary of the logic cell and the first power line positioned at the upper side of the boundary of the logic cell to be disposed in a zigzag shape; the second power line may be positioned at upper and lower sides based on the boundary of the logic cell, respectively; and the separation areas of the second conductive line may alternately overlap the second power line disposed under the boundary of the logic cell and the second power line disposed on the boundary of the logic cell to be disposed in a zigzag shape.

The second conductive line may be formed as a single wire connected along the second direction, and then an additional process may be performed to remove at least a portion of the second conductive line, so that the separation area may be formed.

In the forming of the second conductive line, the second conductive lines disposed on an imaginary line extending along the second direction may be formed to be separated from each other.

Another embodiment provides a semiconductor device including: a plurality of logic cells, wherein each of the plurality of logic cell includes a plurality of first conductive lines and a plurality of first power lines, a plurality of second conductive lines disposed on the plurality of first conductive lines and the plurality of first power lines, and a plurality of third conductive lines and a plurality of second power lines disposed on the plurality of second conductive lines; the first conductive line, the first power line, the third conductive line, and the second power line extend in a first direction; the second conductive line extends in a second direction crossing the first direction; the second conductive line includes a separation area disposed adjacent to a boundary of the logic cell; the separation areas of the second conductive line are alternately positioned at a lower side and an upper side based on the boundary of the logic cell to be disposed in a zigzag form; and points at which the second conductive lines and the third conductive lines overlap have second hit points to which the second conductive lines and the third conductive lines are able to be connected, except for a point adjacent to the separation area of the second conductive line.

A disposition form of the separation areas of the second conductive line adjacent to the upper edge of the logic cell and a disposition form of the separation areas of the second conductive line adjacent to the lower edge of the logic cell may be substantially the same or symmetrical.

Another embodiment provides a semiconductor device including: a plurality of logic cells, wherein each of the plurality of logic cells includes a first power line positioned at two edges of the logic cell facing each other, a first conductive line positioned between the first power lines, a second conductive line crossing the first power line and the first conductive line; a second power line that crosses the second conductive line and is positioned at the two edges of the logic cell facing each other, and a third conductive line positioned between the second power lines; the second conductive line includes a separation area disposed adjacent to a boundary of the logic cell; the separation areas of the second conductive line are alternately positioned at a lower side and an upper side based on the boundary of the logic cell to be disposed in a zigzag form; points at which the first conductive lines and the second conductive lines overlap have first hit points to which the first conductive lines and the second conductive lines are able to be connected, except for a point adjacent to the separation area of the second conductive line; and points at which the second conductive lines and the third conductive lines overlap have second hit points to which the second conductive lines and the third conductive lines are able to be connected, except for a point adjacent to the separation area of the second conductive line.

The separation areas of the second conductive line may alternately overlap a lower edge and an upper edge of the first power line to be disposed in a zigzag form; and the separation areas of the second conductive line may be alternately positioned at a lower side and an upper side based on the second power line to be disposed in a zigzag form.

A disposition form of the separation areas of the second conductive line adjacent to the upper edge of the logic cell and a disposition form of the separation areas of the second conductive line adjacent to the lower edge of the logic cell may be substantially the same or symmetrical.

According to the embodiments, it is possible to sufficiently secure a process margin between wires of a semiconductor device.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A semiconductor device, comprising a plurality of logic cells, wherein:
each logic cell of the plurality of logic cells includes:
a plurality of first conductive lines and a plurality of first power lines,
a plurality of second conductive lines on the plurality of first conductive lines and the plurality of first power lines, and
a plurality of third conductive lines and a plurality of second power lines on the plurality of second conductive lines,
the first conductive line, the first power line, the third conductive line, and the second power line extend in a first direction,
the second conductive line extends in a second direction crossing the first direction,
the second conductive line includes separation areas adjacent to a boundary of a logic cell of the plurality of logic cells,
the separation areas of the second conductive line are alternately positioned at a lower side and an upper side based on the boundary of the logic cell to be disposed in a zigzag form, and
points at which the first conductive lines and the second conductive lines overlap have first hit points to which the first conductive lines and the second conductive lines are able to be connected, except for a point adjacent to the separation area of the second conductive line.

2. The semiconductor device as claimed in claim 1, wherein: points at which the second conductive lines and the third conductive lines overlap have second hit points to which the second conductive lines and the third conductive lines are able to be connected, except for a point adjacent to the separation area of the second conductive line.

3. The semiconductor device as claimed in claim 2, wherein:
the first power line overlaps the boundary of a logic cell of the plurality of logic cells, and
the separation areas of the second conductive line alternately overlap a lower edge and an upper edge of the first power line to be disposed in a zigzag form.

4. The semiconductor device as claimed in claim 3, wherein: a width of the first power line is wider than that of the first conductive line.

5. The semiconductor device as claimed in claim 2, wherein:
the second power line overlaps the boundary of the logic cell of the plurality of logic cells, and
the separation areas of the second conductive line are alternately positioned at a lower side and an upper side based on the second power line to be disposed in a zigzag form.

6. The semiconductor device as claimed in claim 5, wherein: a width of the second power line is substantially the same as that of the third conductive line.

7. The semiconductor device as claimed in claim 2, wherein: a disposition form of the separation areas of the second conductive line adjacent to an upper edge of the logic cell of the plurality of logic cells and a disposition form of the separation areas of the second conductive line adjacent to a lower edge of the logic cell of the plurality of logic cells are substantially the same.

8. The semiconductor device as claimed in claim 7, wherein:
a number of first hit points overlapping the second conductive line positioned at a first column is the same as a number of first hit points overlapping the second conductive line positioned at a second column, and
a number of second hit points overlapping the second conductive line positioned at the first column is the same as a number of second hit points overlapping the second conductive line positioned at the second column.

9. The semiconductor device as claimed in claim 7, wherein:
within one logic cell of the plurality of logic cells, each of the plurality of second conductive lines overlaps five first conductive lines and five third conductive lines, and
each of the plurality of second conductive lines overlaps four first hit points and four second hit points.

10. The semiconductor device as claimed in claim 2, wherein: a disposition form of the separation areas of the second conductive line adjacent to an upper edge of the logic cell of the plurality of logic cells and a disposition form of the separation areas of the second conductive line adjacent to a lower edge of the logic cell are symmetrical to each other.

11. The semiconductor device as claimed in claim 10, wherein:
a number of first hit points overlapping the second conductive line positioned at a first column is different from a number of first hit points overlapping the second conductive line positioned at a second column, and
a number of second hit points overlapping the second conductive line positioned at the first column is different from a number of second hit points overlapping the second conductive line positioned at the second column.

12. The semiconductor device as claimed in claim 10, wherein:
within one logic cell of the plurality of logic cells, each of the plurality of second conductive lines overlaps five first conductive lines and five third conductive lines,
some of the plurality of second conductive lines overlap three first hit points and three second hit points, and
the remainder of the plurality of second conductive lines overlap five first hit points and five second hit points.

13. The semiconductor device as claimed in claim 2, wherein:
the first power line is positioned at upper and lower sides based on the boundary of the logic cell of the plurality of logic cells, respectively
the separation areas of the second conductive line alternately overlaps the first power line positioned at the lower side of the boundary of the logic cell of the plurality of logic cells and the first power line positioned at the upper side of the boundary of the logic cell of the plurality of logic cells to be disposed in a zigzag shape,
the second power line is positioned at upper and lower sides based on the boundary of the logic cell of the plurality of logic cells, respectively and
the separation areas of the second conductive line alternately overlaps the second power line under the boundary of the logic cell of the plurality of logic cells and the second power line disposed on the boundary of the logic cell of the plurality of logic cells to be disposed in a zigzag shape.

14. The semiconductor device as claimed in claim 2, wherein: the second conductive line is formed as a single wire connected along the second direction, and then an additional process is performed to remove at least a portion of the second conductive line, so that the separation area is formed.

15. The semiconductor device as claimed in claim 2, wherein:
in the forming of the second conductive line, the second conductive lines on an imaginary line extending along the second direction are formed to be separated from each other.

16. A semiconductor device, comprising a plurality of logic cells,
wherein:
each of the plurality of logic cells includes
a plurality of first conductive lines and a plurality of first power lines,
a plurality of second conductive lines disposed on the plurality of first conductive lines and on the plurality of first power lines, and
a plurality of third conductive lines and a plurality of second power lines disposed on the plurality of second conductive lines,
the first conductive line, the first power line, the third conductive line, and the second power line extend in a first direction,
the second conductive line extends in a second direction crossing the first direction,
the second conductive line includes a separation area disposed adjacent to a boundary of a logic cell of the plurality of logic cells,
the separation areas of the second conductive line are alternately positioned at a lower side and an upper side based on the boundary of the logic cell so as to be disposed in a zigzag form, and
points at which the second conductive lines and the third conductive lines overlap have second hit points to which the second conductive lines and the third conductive lines are able to be connected, except for at a point adjacent to the separation area of the second conductive line.

17. The semiconductor device as claimed in claim 16, wherein: a disposition form of the separation areas of the second conductive line adjacent to an upper edge of the logic cell of the plurality of logic cells and a disposition form of the separation areas of the second conductive line adjacent to a lower edge of the logic cell are substantially the same or symmetrical.

18. A semiconductor device, comprising a plurality of logic cells,
wherein:
each of the plurality of logic cell includes:
a first power line positioned at two edges of the logic cell facing each other,
a first conductive line positioned between the first power lines,
a second conductive line crossing the first power line, and the first conductive line;
a second power line that crosses the second conductive line and is positioned at the two edges of the logic cell facing each other, and
a third conductive line positioned between the second power lines,
the second conductive line includes a separation area disposed adjacent to a boundary of the logic cell,
the separation areas of the second conductive line are alternately positioned at a lower side and an upper side based on the boundary of the logic cell to be disposed in a zigzag form,
points at which the first conductive lines and the second conductive lines overlap have first hit points to which the first conductive lines and the second conductive lines are able to be connected, except for a point adjacent to the separation area of the second conductive line, and
points at which the second conductive lines and the third conductive lines overlap have second hit points to which the second conductive lines and the third conductive lines are able to be connected, except for a point adjacent to the separation area of the second conductive line.

19. The semiconductor device as claimed in claim 18, wherein:
the separation areas of the second conductive line alternately overlap a lower edge and an upper edge of the first power line to be disposed in a zigzag form, and
the separation areas of the second conductive line are alternately positioned at a lower side and an upper side based on the second power line to be disposed in a zigzag form.

20. The semiconductor device as claimed in claim 18, wherein: a disposition form of the separation areas of the second conductive line adjacent to an upper edge of a logic cell and a disposition form of the separation areas of the second conductive line adjacent to a lower edge of the logic cell are substantially the same or symmetrical.
